(19) United States
(12) Patent Application Publication
(10) Pub. No.: US 2024/0373596 A1
(43) Pub. Date: Nov. 7, 2024

(54) ACTIVELY CONTROLLED IMMERSION COOLING SYSTEM AND METHOD

(71) Applicant: LIQUIDSTACK HOLDING B.V., Amsterdam (NL)

(72) Inventors: Kar-Wing Lau, Hong Kong (HK); Wai Sing Cheng, Hong Kong (HK); Joseph Capes, Northborough, MA (US)

(21) Appl. No.: 18/777,214

(22) Filed: Jul. 18, 2024

Related U.S. Application Data
(63) Continuation of application No. PCT/IB2023/000025, filed on Jan. 18, 2023.
(60) Provisional application No. 63/300,501, filed on Jan. 18, 2022.

(51) Int. Cl. H05K 7/20

(52) U.S. Cl. CPC H05K 7/20836; H05K 7/20236; H05K 7/20781

(57) ABSTRACT

Embodiments of immersion cooling systems and methods of operation are described herein. In one example, a method of operating an immersion cooling system can include providing an immersion cooling system, providing IT equipment to be cooled by the immersion cooling system, performing a readiness check of the immersion cooling system, performing a performance check of the immersion cooling system, determining a cooling power of the immersion cooling system, determining a cooling need of the IT equipment, determining a power delta, and adjusting a setting of the immersion cooling system or a setting of the IT equipment to reduce the power delta if the power delta is nonzero. Other examples may be described and claimed.

### CROSS-REFERENCE TO RELATED APPLICATIONS

Pursuant to 35 U.S.C. 120 and 365 (c), this application is a continuation of International Application PCT/IB2023/000025, filed on Jan. 18, 2023, which designates the United States and claims priority to U.S. Patent Application No. 63/300,501, filed on Jan. 18, 2022, each of which is hereby incorporated by reference in its entirety.

### TECHNICAL FIELD

This disclosure relates to immersion cooling systems and methods for actively controlling immersion cooling systems.

### BACKGROUND

Data centers house information technology (IT) equipment for the purposes of storing, processing, and disseminating data and applications. IT equipment may include electronic devices, such as servers, storage systems, power distribution units, routers, switches, and firewalls.

During use, IT equipment consumes electricity and produces heat as a byproduct. A data center containing thousands of servers requires a dedicated IT cooling system to manage the heat produced. The heat must be captured and rejected from the data center. If the heat is not removed, ambient temperature within the data center will rise above an acceptable threshold and temperature-induced performance throttling of electronic devices (e.g., microprocessors) may occur.

Data centers are energy-intensive facilities. It is not uncommon for a data center to consume over fifty times more energy per square foot than a typical commercial office building. Electricity use in data centers is attributable to a variety of systems, including IT equipment, air management systems, mechanical systems, electrical systems (e.g., power conditioning systems), and cooling systems for IT equipment. Examples of IT cooling systems include precision air conditioning systems, direct expansion systems, chilled water systems, free cooling systems, humidification systems, and direct liquid cooling systems. In some data centers, IT cooling and power conditioning systems account for over half of all electricity use.

Most data centers rely on precision air conditioning systems for IT cooling. Precision air conditioners employ a vapor-compression cycle, similar to residential air conditioners. Although air conditioning technology is well-suited for comfort cooling office space, it is not well-suited for cooling thousands of relatively small, hot devices distributed throughout a large data center. Air has a relatively low heat capacity, which necessitates moving and conditioning large amounts of air to cool IT equipment. Consequently, air conditioners suffer from poor thermodynamic efficiency, which translates to high operating expense.

To reduce energy consumption and operating expense, there is a need to cool IT equipment more efficiently. Accordingly, advancements that improve efficiency, performance, reliability, and sustainability of IT cooling systems are needed.

### SUMMARY

In one aspect, a method of operating an immersion cooling system may include providing an immersion cooling system. The method may include providing IT equipment to be cooled by the immersion cooling system. The method may include performing a readiness check of the immersion cooling system. The method may include performing a performance check of the immersion cooling system. The method may include determining a cooling power of the immersion cooling system. The method may include determining a cooling need of the IT equipment. The method may include determining a power delta. The power delta may be a difference between the cooling power and the cooling need. The method may include adjusting a setting of the immersion cooling system or a setting of the IT equipment to reduce the power delta if the power delta is nonzero. The readiness check may include testing a system component prior to starting the immersion cooling system. The readiness check may include determining if a measured value of the system component is within a range of allowable values. The readiness check may include issuing a warning notification if the measured value is outside the range of allowable values. The readiness check may include preventing the immersion cooling system from starting until the measured value is within the range of allowable values. Performing the performance check may include determining a performance value of a subsystem of the immersion cooling system based on measured values during operation of the immersion cooling system. Performing the performance check may include determining if the performance value is within a range of allowable values. Performing the performance check may include issuing a warning notification if the performance value is outside the range of allowable values. Determining the cooling power of the immersion cooling system may include measuring a heat removal rate of a condenser within an immersion tank of the immersion cooling system. The condenser may be configured to transfer heat from a dielectric vapor in the immersion tank to coolant flowing through the condenser. Determining the cooling power of the immersion cooling system may include measuring a heat rejection rate of a heat exchanger of the immersion cooling system. The heat exchanger may be configured to transfer heat from a coolant to ambient air. Determining the cooling need of the IT equipment may include measuring real-time electric power consumption by the IT equipment. Determining the cooling need of the IT equipment may include measuring a dielectric vapor temperature in a headspace of an immersion tank of the immersion cooling system. Adjusting a setting of the immersion cooling system to reduce the power delta may include adjusting at least one of a coolant pump speed setting, a heat exchanger fan speed setting, or a control valve setting with a PID controller. Adjusting a setting of the IT equipment to reduce the power delta may include throttling electric power supplied to the IT equipment, idling the IT equipment, or powering down the IT equipment.

In another aspect, an actively controlled immersion cooling system may include an electronic control unit configured to perform a readiness check of an immersion cooling system, perform a performance check of the immersion cooling system, determine a cooling power of the immersion cooling system, determine a cooling need of IT equipment to be cooled, determine a power delta. The power delta may be a difference between the cooling power and the cooling need. The electronic control unit may be configured to adjust a setting of the immersion cooling system or a setting of the IT equipment to reduce the power delta if the power delta is nonzero. The immersion cooling system may include an immersion tank having an upper portion and a lower portion, and an array of temperature sensors having a plurality of temperature sensors arranged vertically in the upper portion of the immersion tank. The electronic control unit may be configured to determine a height of concentrated vapor zone using one of more temperature sensors and adjust a setting of the immersion cooling system or a setting of the IT equipment to until the height of concentrated vapor zone is within a range of pre-determined values. Determining a cooling power of the immersion cooling system may include determining a heat rejection rate of a liquid-to-air heat exchanger.

In another aspect, a method of adjusting system settings of an immersion cooling system based on predicted weather information may include receiving a predicted weather information, including a predicted time of a weather change. The method may include determining a target immersion cooling system setting based on the predicted weather information. The method may include determining a transition time needed to transition from a current immersion cooling system setting to the target immersion cooling system setting. The method may include ramping the current immersion cooling system setting toward the target immersion cooling system setting prior to the predicted time of the weather change. The predicted weather information may include a predicted air temperature, a predicted humidity, and a predicted wind speed. The target immersion cooling system setting may be a target pump speed, a target heat exchanger fan speed, or a target control valve setting. Ramping the current immersion cooling system setting toward the target immersion cooling system setting prior to the predicted time of the weather change may include ramping the current immersion cooling system setting toward the target immersion cooling system setting at least one transition duration prior to the predicted time of the weather change. Issuing a warning notification if the current immersion cooling system setting cannot be ramped to the target immersion cooling system setting prior to the predicted time of the weather change.

In another aspect, an actively controlled immersion cooling system configured to adjust system settings based on predicted weather information may include an electronic control unit. The electronic control unit may be configured to receive predicted weather information, including a predicted time of a weather change. The electronic control unit may be configured to determine a target immersion cooling system setting based on the predicted weather information. The electronic control unit may be configured to determine a transition time needed to transition from a current immersion cooling system setting to the target immersion cooling system setting. The electronic control unit may be configured to ramp the current immersion cooling system setting toward the target immersion cooling system setting prior to the predicted time of the weather change. The predicted weather may include a predicted air temperature, a predicted humidity, or a predicted wind speed. The target immersion cooling system setting may be a target pump speed, a target heat exchanger fan speed, or a target control valve setting.

This Summary is provided to introduce a selection of concepts in a simplified form that are further described below in the Detailed Description. This Summary is not intended to identify key features or essential features of the claimed subject matter, nor is it intended to be used to determine the scope of the claimed subject matter.

### BRIEF DESCRIPTION OF THE DRAWINGS

FIG. 1 shows a method of operating an immersion cooling system.

FIG. 2 shows a two-phase immersion cooling system capable of operating according to the method of FIG. 1.

FIG. 3 shows a heat transfer pathway of the two-phase immersion cooling system of FIG. 2.

FIG. 4 shows an example of control logic for the two-phase immersion cooling system of FIG. 2 operating according to the method of FIG. 1.

FIG. 5 shows a diagram of a PID controller adjusting a coolant pump speed setting based on a measured dielectric vapor temperature.

FIG. 6 shows a diagram of a PID controller adjusting a heat exchanger fan speed setting based on a measured dielectric vapor temperature.

FIG. 7 shows a diagram of a PID controller adjusting a control valve setting based on a measured dielectric vapor temperature.

FIG. 8 shows a single-phase immersion cooling system capable of operating according to the method of FIG. 1.

FIG. 9 shows a heat transfer pathway of the-single phase immersion cooling system of FIG. 8.

FIG. 10 shows a single-phase immersion cooling system capable of operating according to the method of FIG. 1.

FIG. 11 shows a heat transfer pathway of the-single phase immersion cooling system of FIG. 10.

FIG. 12 shows data collected from a conventional immersion cooling system over a span of several days.

FIG. 13 shows a method of adjusting cooling power of an immersion cooling system based on predicted weather information.

FIG. 14A shows a plot of dielectric liquid level in an immersion cooling system over a time period of continuous operation.

FIG. 14B shows a plot of power consumption by IT equipment in the immersion cooling system over the time period of FIG. 14A

FIG. 14C show a plot of vapor pressure in the immersion cooling system over the time period of FIG. 14A.

FIG. 14D show a plot of dielectric fluid temperature in the immersion cooling system over the time period of FIG. 14A.

FIG. 14E shows a plot of determined dielectric liquid loss in the immersion cooling system over the time period of FIG. 14A.

### DETAILED DESCRIPTION OF EMBODIMENTS

Direct liquid cooling systems present a more effective and efficient alternative to air conditioning systems for data center applications. One form of direct liquid cooling is immersion cooling. In an immersion cooling system, an electronic device is immersed in dielectric fluid. Waste heat from the electronic device is transferred to the fluid and then rejected outside the data center. Since waste heat is not released into the ambient air of the data center, a precision air conditioning system is not needed.

Immersion cooling systems achieve significantly higher heat transfer rates than air conditioning systems. Immersion cooling systems are capable of cooling electronic devices with high heat flux, such as high-performance computing (HPC) servers with multiple graphics processing units (GPUs) with ease. Immersion cooling systems may employ single phase or two-phase technology.

In a single-phase immersion cooling system, electronic devices are immersed in a dielectric fluid, such as mineral oil or hydrofluoroether. Waste heat from the electronic devices is transferred to and warms the fluid. The warmed fluid is pumped from the immersion cooling system to a heat rejection system, such as an evaporative cooling tower, dry cooler, or chilled water loop, that captures waste heat from the fluid and rejects the heat outside the data center.

In a two-phase immersion cooling system, an electronic device is immersed in a dielectric fluid, such as hydrofluoroether. During use, waste heat from the electronic device is absorbed by the fluid, resulting in localized vaporization of the fluid. Vapor rises into a headspace of the tank and is condensed by a condenser. Heat from the vapor is transferred to coolant circulating through the condenser, thereby warming the coolant. The warmed coolant is then pumped from the condenser to a heat rejection system, such as an evaporative cooling tower, dry cooler, or chilled water loop, which captures the waste heat from the fluid and rejects the heat outside the data center.

Conventional immersion cooling systems may fail to actively adjust cooling power to match a dynamic heat load of IT equipment being cooled. Conventional immersion cooling systems may fail to respond to changing conditions within the cooling system, within the data center, and/or outside the data center. Conventional cooling systems may fail to adjust system operation based on cooling system readiness and performance, dynamic heat load of the IT equipment, and/or weather conditions outside the data center. As a result, in some instances, conventional immersion cooling systems may provide more cooling capacity than is required and may consume more energy than is necessary to adequately cool the IT equipment. In other instances, conventional cooling systems may fail to meet a steady-state or transient cooling demand of the IT equipment, potentially resulting in performance throttling or costly downtime.

The performance and efficiency of air cooling devices is affected by ambient air conditions, such as air temperature, humidity, wind, and precipitation. Conventional immersion cooling systems that rely on outdoor dry coolers may be unable to respond to changing weather conditions, leaving them vulnerable to failing to provide sufficient cooling power when local weather changes suddenly.

In view of these shortcomings, an actively controlled immersion cooling system is needed that determines a dynamic heat load of IT equipment being cooled and automatically adjusts parameters to match cooling power to the cooling demand. The system may receive and monitor parameters within the system and/or weather parameters outside the data center, and actively adjust system settings in response to the parameters to improve performance and efficiency.

In addition to providing real-time monitoring of system, facility, and outdoor parameters and actively adjusting a method of operation based on those parameters, the system may also receive predictive weather information and adjust system operation based on predicted changes in weather conditions outside the data center that may impact heat rejection performance of an outdoor heat exchanger.

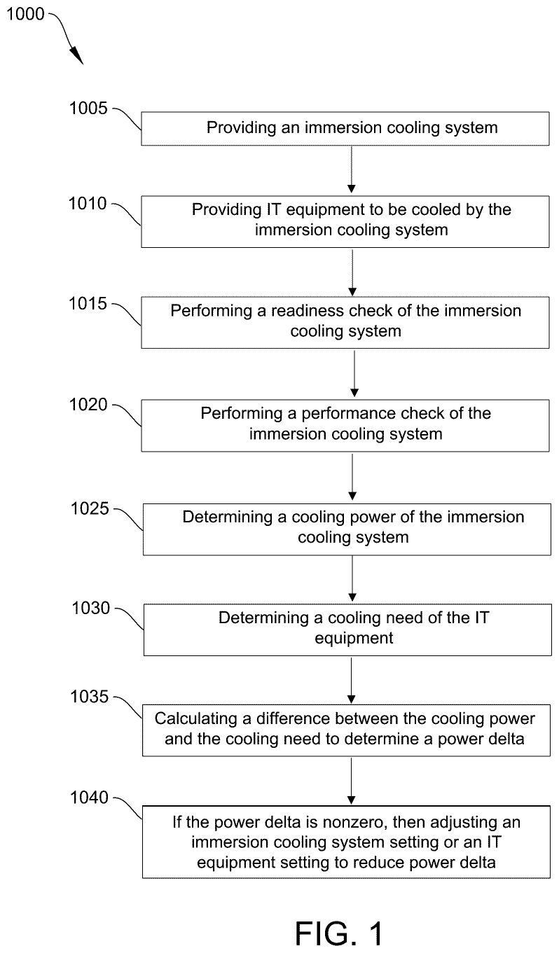

A method 1000 of operating an immersion cooling system is shown in FIG. 1. The method 1000 may include a step 1005 of providing an immersion cooling system.

The method 1000 may include a step 1010 of providing IT equipment 800 to be cooled by the immersion cooling system. The method 1000 may include a step 1015 of performing a readiness check of the immersion cooling system 100. The method 1000 may include a step 1020 of performing a performance check of the immersion cooling system 100. The method 1000 may include a step 1025 of determining a cooling power of the immersion cooling system 100 based on measured values. The method 1000 may include a step 1030 of determining a cooling need of the IT equipment 800. The method 1000 may include a step of comparing the cooling power to the cooling need, and if a power delta exists, adjusting the immersion cooling system and/or IT equipment to reduce the power delta. The steps may be performed in the order shown or in any other suitable order. In some examples, one or more steps may be added to the method 1000. In some examples, one or more steps may be omitted from the method 1000. In some examples, one or more steps of the method may be performed concurrently.

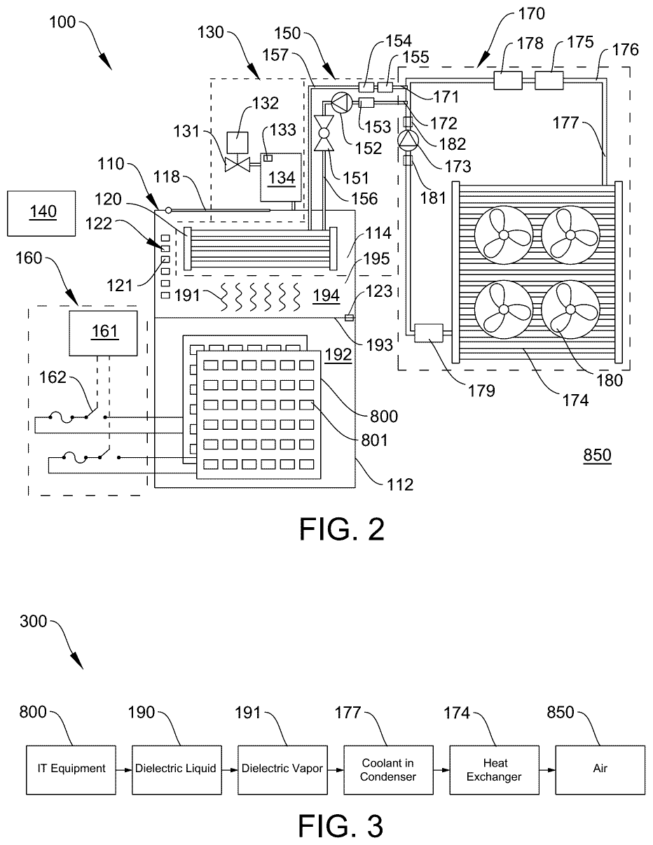

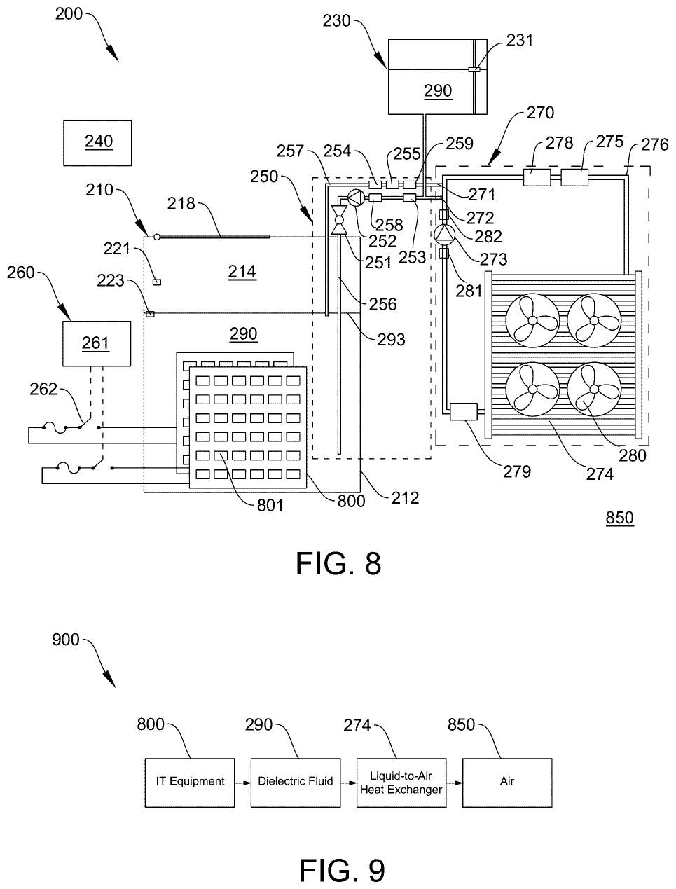

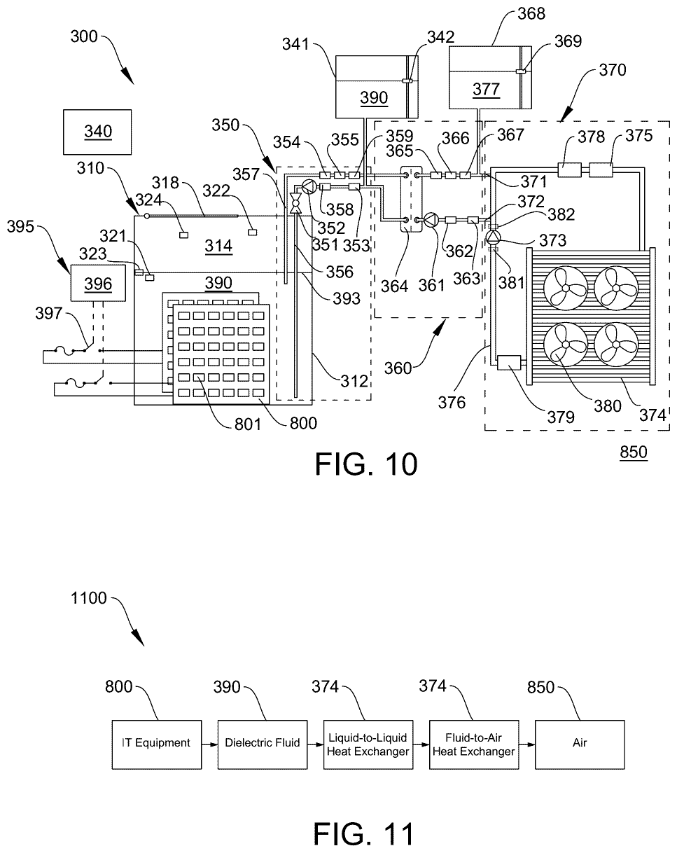

Several embodiments of actively controlled immersion cooling systems are described herein. A first embodiment is an actively controlled two-phase immersion cooling system 100 shown in FIG. 2. A second embodiment is an actively controlled single-phase immersion cooling system 200 shown in FIG. 8. A third embodiment is an actively controlled single-phase immersion cooling system 300 shown in FIG. 10. The immersion cooling systems (100, 200, 300) are each capable of operating according to the method 1000 of FIG. 13 but may do so in different ways. The immersion cooling systems (100, 200, 300) are each capable of operating according to a method 1300 of FIG. 13 but may do so in different ways. Detailed descriptions of the embodiments and corresponding methods of operation are described below.

FIG. 2 shows an actively controlled two-phase immersion cooling system 100 is shown in FIG. 2. The system 100 may include an immersion tank assembly 110. The system 100 may include a venting system 130. The system 100 may include a heat capture system 150. The system 100 may include a heat rejection system 170. The system 100 may include a power supply system 160. The system 100 may include an electronic control unit 140 with programmable logic control.

The immersion tank assembly 110 may include an immersion tank 112. The immersion tank assembly 110 may include an immersion tank 112 partially filled with dielectric fluid 190. IT equipment 800 may be immersed in the dielectric fluid 190. The IT equipment 800 may be connected to electrical power via a power relay. The immersion tank 112 may be enclosed by a lid 118.

The immersion tank 112 may have an upper portion and a lower portion. The upper portion may be located above a liquid line 193. The lower portion may be located below the liquid line 193. The liquid line 193 may be an interface between gases (e.g., air and dielectric vapor 191) in a headspace 114 of the tank 112 and dielectric liquid 192 in the lower portion of the tank 112. The immersion tank 112 may include a temperature sensor 121 located in the headspace 114 of the tank 112.

The immersion tank 112 may have an opening in the upper portion. When open, the lid 118 may provide access to an interior volume of the immersion tank 112 to facilitate insertion and removal of IT equipment 800 (e.g., servers, switches, or power electronics). When closed, the lid 118 may enclose the opening and prevent vapor loss. The lid 118 may seal the opening. The lid 118 may hermetically seal the opening.

The immersion tank 112 may be partially filled with dielectric fluid 190. The fluid 190 may be selected to have a boiling point that is less than an operating temperature of the IT equipment 800. When the IT equipment is operating, fluid in contact with the IT equipment may boil locally and produce vapor. Vapor may rise through the fluid bath and into the headspace 114 of the tank 112. The vapor may settle atop the liquid line 193, forming a vapor zone 194.

The immersion tank 112 may include an array of temperature sensors 122 having a plurality of temperature sensors located in the headspace 114 of the immersion tank 112 and arranged in a vertical configuration, as shown in FIG. 2. The temperature sensor array 122 may be configured to measure temperatures at multiple locations vertically in the headspace. By comparing temperature values from the plurality of sensors, the temperature sensor array 122 can be used to determine a height of the vapor zone 195 within the headspace 114 during operation. The determined vapor zone height may indicate that the liquid line 193 has dropped below a top surface of the electronic devices 800, which is undesirable since the electronic devices will not be adequately cooled. In this example, a warning notice may be issued by the system 100, indicating a low fluid level, and instructing an operator to replenish the fluid.

In one example, the electronic control unit 140 may be configured to determine the height of the concentrated vapor zone 195 using the array of temperature sensors 122 and adjust a setting of the immersion cooling system 100 or a setting of the IT equipment 800 until the height of concentrated vapor zone 195 is within a range of pre-determined values.

The immersion tank assembly 110 may include a condenser 120. The condenser 120 may be a cooling coil. The condenser 120 may be a cooling coil that receives the coolant 177, such as chilled water, water-glycol mixture, or refrigerant, from the heat rejection system 170. The condenser 120 may be located in the headspace 114 of the tank 112. Coolant 177 may flow through the condenser 120 during operation. As the coolant 177 flows through the condenser 120, the coolant may absorb heat from dielectric vapor in the headspace 114. The absorbed heat may warm the coolant 177.

To minimize energy consumption, the condenser 120 may operate at a temperature at or slightly above room temperature. In one example, the condenser 120 may receive and circulate coolant at a temperature of about 33 C. when ambient air temperature is 30 C. In another example, the condenser 120 may receive and circulate coolant at a temperature of about 25 to 40 C. In yet another example, the condenser 120 may receive and circulate coolant at a temperature of about 30 to 36 C. In still another example, the condenser 120 may receive and circulate coolant at a temperature of about 0 to 10 degrees above an ambient air temperature. In still another example, the condenser 120 may receive and circulate coolant at a temperature of about 0 to 15 degrees above an ambient air temperature.

The heat capture system 150 may capture heat from the immersion tank 112. The heat capture system 150 may circulate coolant 177 between the condenser 120 and the heat rejection system 170. The heat capture system 150 may include a fluid supply passage 156 to transport coolant 177 from the heat rejection system 170 to the condenser 120. The heat capture system 150 may include a fluid return passage 157 to transport coolant 177 from the condenser 120 to the heat rejection system 170. The heat capture system 150 may include a coolant pump 152. The coolant pump 152 may be located in the fluid supply passage 156 or the fluid return passage 157. The heat capture system 150 may include an inlet temperature sensor 153 in the fluid supply passage 156. The heat capture system 150 may include an outlet temperature sensor 154 in the fluid return passage 157.

The heat rejection system 170 may include a coolant loop 176. The coolant loop 176 may include an inlet 171 and an outlet 172. The heat rejection system 170 may include a heat exchanger 174, such as an evaporative cooling tower, dry cooler, or other suitable liquid-to-air heat exchanger. The heat rejection system 170 may include a coolant pump 173. The coolant pump 173 may circulate coolant 177 through the heat exchanger 174. The heat exchanger 174 may reject heat from the coolant 177 to the environment (e.g., outside the data center).

The heat rejection system 170 may include a flow meter 175. The heat rejection system 170 may include an inlet temperature sensor 178 located upstream of the heat exchanger 174. The heat rejection system 170 may include an outlet temperature sensor 179 located downstream of the heat exchanger 174. The inlet temperature sensor 178 may determine a temperature of coolant 177 entering the heat exchanger 174. The outlet temperature sensor 179 may determine a temperature of coolant 177 exiting the heat exchanger.

The venting system 130 may be fluidly connected to the headspace 114 of the tank 112. The venting system 130 may include a pressure relief valve 131. The venting system 130 may include a solenoid 132 configured to actuate the pressure relief valve 131. The venting system 130 may include a vapor chamber 134. The venting system 130 may include a pressure sensor 133. The venting system 130 may receive vapor from the tank 112 and, when necessary to avoid overpressurization of the tank 112, the solenoid may actuate the pressure relief valve 131 to reduce pressure within the tank 112.

The two-phase cooling system 100 may be electronically controlled by an electronic control unit 140. The control unit 140 may receive inputs from a plurality of sensors configured to measure flow rates, fluid pressures, fluid temperatures, fluid levels, vapor pressures, and vapor temperatures within the system. Based on the inputs received, the control unit 140 may enable active control of the cooling system 100 by adjusting system settings to match cooling power delivered by the system 100 to cooling demand of the IT equipment 800. The control unit 140 may monitor the sensor inputs in real-time and continuously adjust the system settings to match the cooling power of the system 200 to the cooling demand of the IT equipment 800.

The control unit 140 may be configured to control components of the heat rejection system 170. For example, the control unit 140 may be configured to adjust a rotational speed of one or more heat exchanger fans 180 to increase or decrease air flow through the heat exchanger and thereby adjust a heat rejection rate. The control unit 140 may be configured to adjust a pump speed of the coolant pump 173 to increase or decrease the coolant flow rate through the heat exchanger 174.

The control unit 140 may be configured to control components of the heat capture system 150. For example, the control unit 140 may be configured to adjust a pump speed of the coolant pump 152 to increase or decrease a coolant flow rate through the condenser 120. The control unit 140 may be configured to adjust the control valve to adjust a pressure differential across the control valve and thereby adjust the coolant pressure within the heat capture system.

The control unit 140 may be configured to control components of the venting system 130. For example, the control unit 140 may be configured to actuate the solenoid 132 to open the pressure relief valve 131 when vapor pressure in the vapor chamber 134 exceeds an allowable level.

The control unit 140 may be configured to control components of the power supply system 160. For example, the control unit 140 may be configured to control one or more power relays 161 and switches 162 of the power supply system 160. The control unit 140 may be configured to throttle power delivery to the IT equipment if the cooling need exceeds the cooling power. The control unit 140 may be configured to halt power delivery to the IT equipment if the cooling power is incapable of meeting the cooling need.

FIG. 3 shows a heat transfer pathway 300 for the two-phase immersion cooling system 100 of FIG. 2. Waste heat generated by the IT equipment 800 is transferred to the dielectric fluid 190, and localized boiling of dielectric liquid produces dielectric vapor 191. The dielectric vapor 191 travels upward through the fluid bath to the headspace 114 of the tank 112. The dielectric vapor 191 condenses when it contacts the condenser 120. Heat is transferred from the dielectric vapor 191 to the coolant 177 flowing through the condenser 120, thereby warming the coolant 177. The warmed coolant 177 flows through the heat capture system 150 to the heat rejection system 170 where it then flows through the liquid-to-air heat exchanger 174. The heat exchanger 174 may include one or more fans 180 that draw air 850 through a radiator of the heat exchanger 174. Heat from the coolant 177 in the heat exchanger 174 may transfer to the air 850 that is drawn through the heat exchanger 174 by the one or more fans 180.

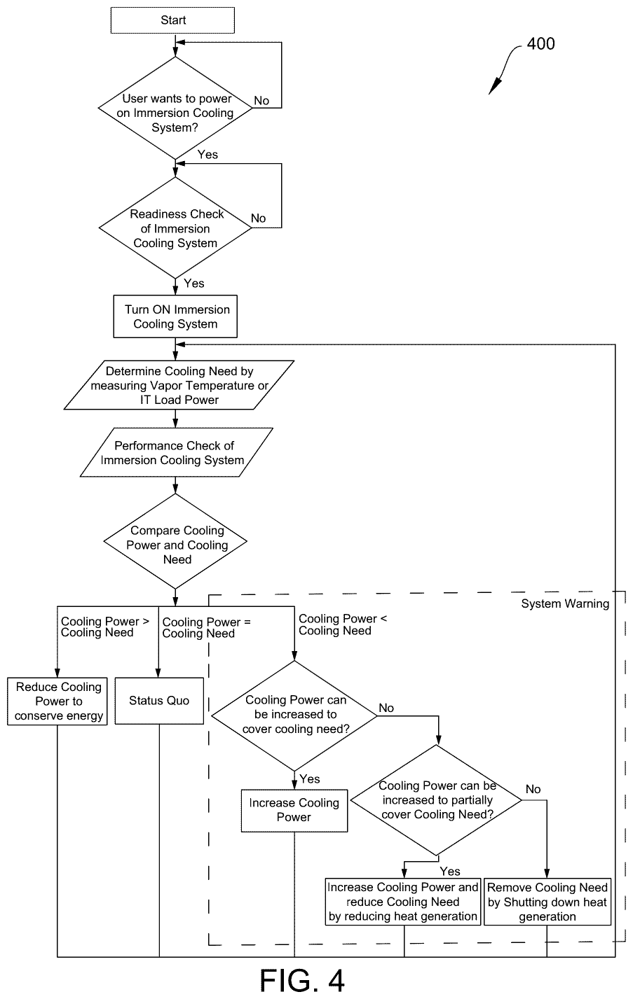

The two-phase immersion cooling system 100 of FIG. 2 may be operated in accordance with the method 1000 of FIG. 1. The method 1000 may serve to assess overall health and performance of the cooling system 100 and its components prior to startup, during operation, and/or after shutdown. The method 1000 may assess system performance in view of a dynamic IT load power and actively adjust the cooling power to match the dynamic IT load power. The method may improve system reliability. The method may improve uptime. The method may improve efficiency. FIG. 4 shows one example of control logic 400 for the two-phase immersion cooling system 100 operating according to the method 1000.

The step 1005 of providing an immersion cooling system may include providing the actively controlled two-phase immersion cooling system 100. The step 1010 of providing IT equipment may include providing IT equipment 800 and placing the IT equipment into the immersion tank 112 of the two-phase immersion cooling system 100. The IT equipment 800 may be submerged in the dielectric fluid 190. The IT equipment 800 may be positioned below the liquid line 193.

The readiness check 1015 may include testing the readiness of certain components and subsystems of the cooling system 100 before fully powering on the system 100. One purpose of the readiness check 1015 may be to identify any malfunctioning components before the system 100 is powered on. Identifying malfunctioning components prior to powering on the cooling system 100 may allow repairs to be made before startup and thereby minimize unplanned downtime. Performing necessary repairs before startup may reduce the likelihood of powering on the IT equipment and then having to throttle or power off the IT equipment due to a cooling system issue.

The readiness check 1015 may include checking the piping of the heat rejection system 170 for leaks. The readiness check 1015 may include checking the piping of the heat capture system 150 for leaks. If a leak is detected, the system 100 may generate a warning notification. If a leak is detected, the system 100 may prevent startup from proceeding until the leak is repaired and no leak is detected.

The readiness check 1015 may include measuring coolant temperature and comparing it to an ambient air 850 temperature.

The readiness check 1015 may include testing a coolant flow rate from the coolant pump 173. The system readiness check 1015 may include operating the coolant pump 173 at a minimum speed and then ramping the coolant pump 173 to a maximum speed. The performance of the coolant pump 173 may be evaluated by reading an output from the flow meter 175. The performance of the coolant pump 173 may be evaluated by determining a pressure differential produced by the coolant pump 173. The pressure differential may be determined by comparing a pressure reading from a first pressure sensor 181 located at the coolant pump 173 inlet to a pressure reading from a second pressure sensor 182 located at the coolant pump 173 outlet.

The readiness check 1015 may include detecting a dielectric liquid level 192 in the immersion tank 112. Detecting the dielectric liquid 192 level may include receiving an output from a liquid level sensor 123 mounted in the immersion tank 112. If the fluid level is too low or too high, the system 100 may generate a warning notification. If the fluid level is too low or too high, the system 100 may prevent startup from proceeding until the fluid level is brought within an acceptable range.

The readiness check 1015 may include detecting a coolant 177 level in the heat exchanger 174. If the coolant level is too low, the system 100 may generate a warning notification. If the coolant level is too low, the system 100 may prevent startup from proceeding until a sufficient amount of coolant is added to the heat exchanger.

The readiness check 1015 may include detecting a coolant 177 level in the condenser 120. If the coolant level is too low, the system 100 may generate a warning notification. If the coolant level is too low, the system 100 may prevent startup from proceeding until the issue is resolved.

The readiness check 1015 may include testing the operability of the control valve 151 in the heat capture system 150 by opening and closing the control valve 151. The control valve 151 may be deemed functional if it as able to fully open and fully close. If the control valve 151 is unable to fully open or close, the system 100 may generate a warning.

The system readiness check 1015 may include measuring power consumption of a component and determining if the power consumption is within an allowable range. For example, the system readiness check 1015 may include measuring power consumption of the coolant pump 152 in the heat rejection system 170 and determining if the power consumption is within an allowable range. The system readiness check 1015 may include measuring power consumption of the coolant pump 152 in the heat capture system 150 and determining if the power consumption is within an allowable range. The system readiness check 1015 may include measuring power consumption of the control valve 151 and determining if the power consumption is within an allowable range. The system readiness check 1015 may include measuring power consumption of the heat exchanger fan 180 and determining if the power consumption is within an allowable range. The system readiness check 1015 may include measuring power consumption of the solenoid 132 and determining if the power consumption is within an allowable range. The system readiness check 1015 may include measuring power consumption of one or more of the sensors and determining if their power consumption is within an allowable range. If any component's power consumption is outside a predetermined allowable range, the system 100 may generate a warning notification. If any component's power consumption is outside its allowable range, the system 100 may prevent startup from proceeding until the issue is resolved.

The readiness check 1015 may include checking a status of one or more power relays connected to the IT equipment 800. The system readiness check may include checking status of one or more power relays connected to one or more system components, such as the coolant pumps (152, 173), control valve 151, or heat exchanger fan 180.

The readiness check 1015 may include measuring fluid pressure in one or more fluid passages of the system 100. The system readiness check 1015 may include determining a pressure drop in the system 100 by comparing pressure measurements at two locations in the system 100. For example, a pressure drop across the heat exchanger 174 may be determined by comparing a pressure measurement at an inlet of the heat exchanger 174 to a pressure measurement at an outlet of the heat exchanger 174. An excessive pressure drop may indicate leakage from the heat exchanger 174.

In one example, the readiness check 1015 may include pumping a predetermined flow of coolant 177 (e.g., 10 liters per minute) through the coolant loop 176 of the heat rejection system 170. Coolant pressure may be measured at one or more points in the coolant loop 176 to determine if the coolant pressure is within an allowable range (e.g., between 2.5 bar and 3.5 bar). If the coolant pressure is outside of the allowable range, the system 100 may generate a warning notification and prevent startup from proceeding until the issue is resolved. If the pressure is below the allowable range, it may indicate leakage in the plumbing of the coolant loop 176.

In another example, the readiness check 1015 may include operating the heat exchanger 174 at a predetermined duty and providing a predetermined flow of coolant 177 through the heat exchanger 174. A temperature differential between coolant entering and exiting the heat exchanger may be determined by measuring and comparing coolant temperatures at the inlet and outlet of the heat exchanger 174. If the temperature differential is lower than an expected theoretical temperature differential, it may indicate that the heat exchanger performance is impaired and the heat exchanger may need cleaning or servicing.

The performance check 1020 may include measuring the heat transfer performance of certain subsystems of the system 100 during operation. For example, the performance check 1020 may include measuring the heat transfer performance of heat capture system 150 during operation. The performance check 1020 may include measuring the heat transfer performance of the heat rejection system 170 during operation.

The performance check 1020 may include measuring the inlet coolant temperature of the heat rejection system 170 with the inlet temperature sensor 178. The performance check 1020 may include comparing the inlet coolant temperature to a range of allowable values and confirming the inlet coolant temperature is within the range of allowable values. If the inlet coolant temperature is outside the range of allowable values, the system 100 may generate a warning notification.

The performance check 1020 may include measuring the outlet coolant temperature of the heat rejection system 170 with the outlet temperature sensor 179. The performance check 1020 may include comparing the outlet coolant temperature to a range of allowable values and confirming the outlet coolant temperature is within the range of allowable values. If the outlet coolant temperature is outside the range of allowable values, the system 100 may generate a warning notification.

The performance check 1020 may include comparing the inlet coolant temperature to the heat exchanger 174 to the outlet coolant temperature from the heat exchanger 174 and determining a temperature differential. The performance check 1020 may include comparing the temperature differential to a range of allowable values and confirming the temperature differential is within the range of allowable values. If the temperature differential is outside the range of allowable values, the system 100 may generate a warning notification.

The performance check 1020 may include measuring the coolant flow rate in the heat rejection system 170 with the flow meter 175. The performance check 1020 may include comparing the coolant flow rate to a range of allowable values and confirming the coolant flow rate is within the range of allowable values. If the coolant flow rate is outside the range of allowable values, the system 100 may generate a warning notification.

The performance check 1020 may include measuring a fan speed of the heat exchanger fan 180 in the heat rejection system 170 with a sensor. The performance check 1020 may include comparing the fan speed to a range of allowable values and confirming the fan speed is within the range of allowable values. If the fan speed is outside the range of allowable values, the system 100 may generate a warning notification.

The performance check 1020 may include measuring the inlet coolant temperature to the condenser 120 with the inlet temperature sensor 153. The performance check 1020 may include comparing the inlet coolant temperature to a range of allowable values and confirming the inlet coolant temperature is within the range of allowable values. If the inlet coolant temperature is outside the range of allowable values, the system 100 may generate a warning notification.

The performance check 1020 may include measuring the outlet coolant temperature from the condenser 120 with the outlet temperature sensor 154. The performance check 1020 may include comparing the outlet coolant temperature to a range of allowable values and confirming the outlet coolant temperature is within the range of allowable values. If the outlet coolant temperature is outside the range of allowable values, the system 100 may generate a warning notification.

The performance check 1020 may include comparing the inlet coolant temperature to the condenser 120 to the outlet coolant temperature from the condenser 120 and determining a temperature differential. The performance check may include comparing the temperature differential to a range of allowable values and confirming the temperature differential is within the range of allowable values. If the temperature differential is outside the range of allowable values, the system 100 may generate a warning notification.

The performance check 1020 may include measuring a coolant flow rate through the condenser 120. The performance check 1020 may include comparing the coolant flow rate to a range of allowable values and confirming the coolant flow rate is within the range of allowable values. If the coolant flow rate is outside the range of allowable values, the system 100 may generate a warning notification.

The performance check 1020 may include measuring a vapor temperature in the immersion tank 112. The performance check 1020 may include comparing the vapor temperature to a range of allowable values and confirming the vapor temperature is within the range of allowable values. If the vapor temperature is outside the range of allowable values, the system 100 may generate a warning notification.

The step of determining the cooling power 1025 of the immersion cooling system 100 may involve determining an actual rate of heat transfer through the system 100. In one example, the cooling power may be substantially equal to a heat removal rate of the condenser 120. The heat removal rate of the condenser 120 may be the rate of heat transferred from the headspace 114 of the immersion tank 112 to the coolant 177 flowing through the condenser 120. In another example, the cooling power may be substantially equal to a heat rejection rate of the heat exchanger 174. The heat rejection rate of the heat exchanger may be the rate of heat transferred from the coolant 177 flowing through the heat exchanger 174 to the environment outside the data center.

The heat removal rate of the condenser 120 may be determined from measured values while the system 100 is operating. In one example, the heat removal rate from the condenser 120 may be calculated from measured values, including an inlet coolant temperature to the condenser 120, an outlet coolant temperature from the condenser 120, and a coolant flow rate through the condenser 120. The inlet coolant temperature may be measured by the inlet temperature sensor 153. The outlet coolant temperature may be measured by the outlet temperature sensor 154. The coolant flow rate may be measured by the flow meter 155. The heat removal rate for the condenser 120 may be determined by the following equation:

$$heat removal {rate}_{condenser} = ( {T}_{outlet} - {T}_{inlet} ) * ( mass flow rate ) * ( heat capacity )$$

where ‘mass flow rate’ is a mass flow rate of coolant, and ‘heat capacity’ is the heat capacity of the coolant.

The performance check 1020 may include measuring actual performance of the heat exchanger 174 at rejecting heat to the environment. The performance check 1020 may include determining a heat rejection rate of the heat exchanger 174 based on measured values. In one example, the heat rejection rate may be calculated using the inlet coolant temperature to the heat exchanger 174, the outlet coolant temperature from the heat exchanger 174, and the coolant flow rate through the heat exchanger 174. The inlet coolant temperature to the heat exchanger 174 may be measured by the inlet temperature sensor 178. The outlet coolant temperature from the heat exchanger 174 may be measured by the outlet temperature sensor 179. The coolant 177 flow rate may be measured by the flow meter 175. The heat rejection rate for the heat exchanger 174 may be determined with the following equation:

$$heat rejection {rate}_{heat exchanger} = ( {T}_{inlet} - {T}_{outlet} ) * ( mass flow rate ) * ( heat capacity )$$

where ‘Tᵢₙₗₑₜ’ is a coolant temperature entering the heat exchanger 174, ‘Tₒᵤₜₗₑₜ’ is the coolant temperature exiting the heat exchanger 174, ‘mass flow rate’ is a mass flow rate of coolant through the heat exchanger 174, and ‘heat capacity’ is the heat capacity of the coolant 177.

The step of determining the cooling need may include measuring the vapor temperature in the headspace 114 of the immersion tank 112. The vapor temperature may be measured with the temperature sensor 121. The vapor temperature may be measured with the array of temperature sensors 122 to assess a height of a vapor zone above the liquid line 193 in view of a height of the condenser 120 above the liquid line 193.

The step of determining the cooling need may include determining the IT load power of the IT equipment 800 within the immersion tank 112. The IT load power may vary with time depending on utilization of the IT equipment. Each piece of IT equipment may fluctuate in power consumption and contribute to IT load power.

The step of determining the cooling need may include measuring total electric power being consumed by the IT equipment. An electric power meter may be used to measure electric power consumption by the IT equipment. Since the IT equipment is immersed it the dielectric fluid, it may be assumed that substantially all of the electric power consumed by the IT equipment is converted to heat.

The step of determining the cooling need may involve the system 100 receiving relevant information from the IT equipment 800 that may be used to calculate the cooling need. For example, the information received from the IT equipment may include CPU utilization rate, CPU temperature, IT equipment temperature, and/or electric power consumption.

The step 1035 of comparing the cooling power to the cooling need may include calculating a power delta between the cooling power and the cooling need.

$$power delta = cooling power - cooling need$$

FIG. 4 shows an example of control logic 400 that may be used by the control unit 140 when comparing cooling power and cooling need. For example, if the cooling power is equal to the cooling need, no action may be required. If the cooling power is not equal to the cooling need, one or more settings of the immersion cooling system 100 may be adjusted to reduce the power delta. If the cooling power is not equal to the cooling need, one or more settings of the IT equipment 800 may be adjusted to reduce the power delta.

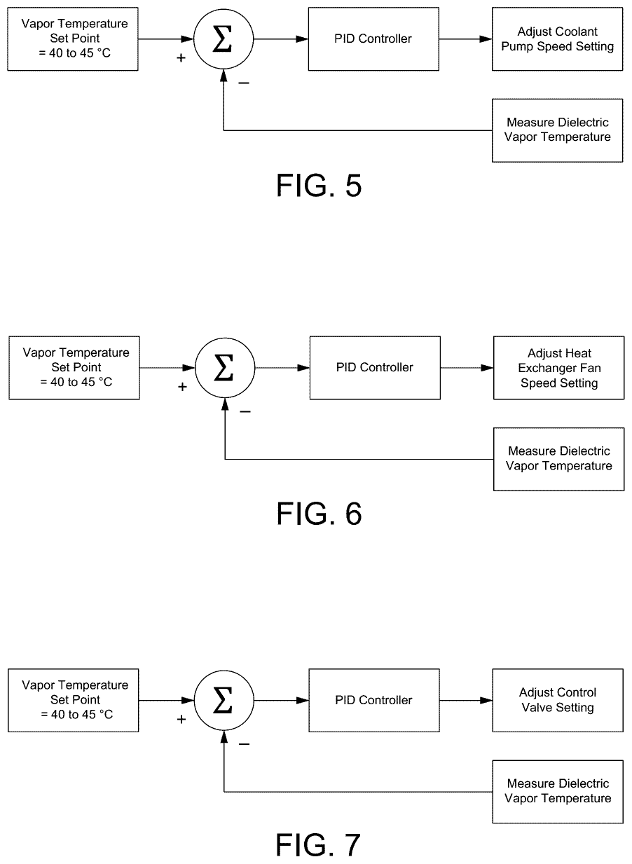

The step 1040 of adjusting a setting of the immersion cooling system 100 may include increasing the coolant pump 173 speed to increase coolant 177 flow through the heat exchanger 174 to increase the cooling power. Adjusting a setting of the immersion cooling system 100 may include decreasing the coolant pump 173 speed to decrease the cooling power. FIG. 5 shows a diagram of a PID controller adjusting the coolant pump 173 speed setting based on a measured dielectric vapor temperature.

The step 1040 of adjusting a setting of the immersion cooling system 100 may include increasing the coolant pump 152 speed to increase the cooling power. Adjusting a setting of the immersion cooling system 100 may include decreasing the coolant pump 152 speed to decrease the cooling power.

The step 1040 of adjusting a setting of the immersion cooling system 100 may include increasing the heat exchanger fan 180 speed to increase the cooling power. Adjusting a setting of the immersion cooling system 100 may include decreasing the heat exchanger fan 180 speed to decrease the cooling power. FIG. 6 shows a diagram of a PID controller adjusting the heat exchanger fan 180 speed setting based on a measured dielectric vapor temperature.

The step 1040 of adjusting a setting of the immersion cooling system 100 may include adjusting an opening angle of the control valve 151. FIG. 7 shows a diagram of a PID controller adjusting the control valve 151 setting based on a measured dielectric vapor temperature.

The step 1040 of adjusting a setting of the IT equipment can include throttling power consumption to reduce the cooling need. Adjusting a setting of the IT equipment can include powering down the IT equipment to reduce the cooling need. Adjusting a setting of the IT equipment can include idling the IT equipment for a period of time.

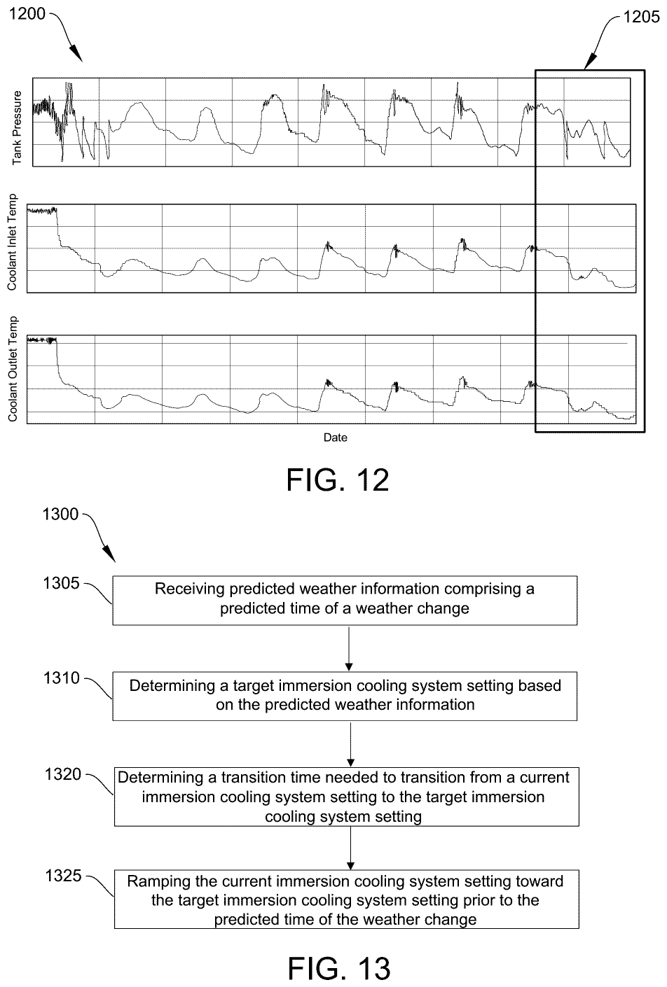

FIG. 12 shows data 1200 collected from a conventional immersion cooling system over a span of several days. The highlighted area 1205 shows how an immersion tank pressure, coolant inlet temperature, and coolant outlet temperature responded to an extreme weather event. The extreme weather event disrupted system performance significantly.

To avoid weather-induced disruptions, the system 100 may be configured to receive predictive weather information and begin to preemptively adjust system settings to maintain a required cooling power.

System components, such as the control valve 151, coolant pump 152, coolant pump 173, and fan 180, may require time to adjust after a setting change has been requested by the control unit 140. For example, a control valve 151 may require several minutes to transition from fully closed to fully open. The coolant pump 152 speed may require several minutes to ramp up or down slowly. The coolant pump 173 speed may require several minutes to ramp up or down slowly. The heat exchanger fan 180 may require several minutes to ramp up or down slowly.

Since the system 100 requires time to respond to changing weather conditions, it may be desirable for the system 100 to predict when the weather will change and begin adjusting system settings in advance. For example, it may be desirable to predict a weather change about 15 minutes in advance to allow the system sufficient time to safely adjust system settings. Due to the high specific heat of the dielectric fluid 190 and coolant 177, the system may have considerable thermal mass. Allowing the system sufficient time to adjust to the predicted weather may be desirable to minimize disruption to operation and efficiency.

The system 100 may receive predictive weather information from any suitable source. The system 100 may receive predictive weather information from a weather service. The system 100 may receive predictive weather information from a weather indicator, such as a barometer.

As shown in FIG. 13, a method 1300 of adjusting cooling power of the system 100 based on predicted weather may include a step 1305 of receiving predicted weather information, including a predicted time of a weather change. The method 1300 may include a step 1310 of determining a target immersion cooling system setting based on the predicted weather information. The method 1300 may include a step 1320 of determining a transition time needed to transition from a current immersion cooling system setting to the target immersion cooling system setting. The method may include a step 1325 of ramping the current immersion cooling system setting toward the target immersion cooling system setting prior to the predicted time of the weather change. To allow the system time to fully transition to the target setting before the weather change occurs, the method may include a step 1325 of ramping the current immersion cooling system setting toward the target immersion cooling system setting at least one transition duration prior to the predicted time of the weather change.

FIG. 8 shows an actively controlled single-phase immersion cooling system 200. The system 200 may include an immersion tank assembly 210. The system 100 may include a liquid transfer system 250. The system 200 may include a heat rejection system 270. The system 200 may include a power supply system 260. The system 200 may include an electronic control unit 240 with programmable logic control.

The immersion tank assembly 210 may include an immersion tank 212. The immersion tank assembly 210 may include an immersion tank 212 partially filled with dielectric fluid 290. IT equipment 800 may be immersed in the dielectric fluid 290. The IT equipment 800 may be connected to electrical power via a power relay. The immersion tank 212 may be enclosed by a lid 218.

The immersion tank 212 may have an upper portion and a lower portion. The upper portion may be located above a liquid line 293. The lower portion may be located below the liquid line 293. The liquid line 293 may be an interface between gases in a headspace 214 of the tank 212 and dielectric liquid in the lower portion of the tank 212. The immersion tank 212 may include a temperature sensor 221 located in the headspace 214 of the tank 212. The immersion tank 212 may include a liquid level sensor 223.

The immersion tank 212 may have an opening in the upper portion. When open, the lid 218 may provide access to an interior volume of the immersion tank 212 to facilitate insertion and removal of IT equipment 800 (e.g., servers, switches, or power electronics). When closed, the lid 218 may enclose the opening and prevent vapor loss. The lid 218 may seal the opening. The lid 218 may hermetically seal the opening.

The liquid transfer system 250 may transfer dielectric fluid 290 between the immersion tank 212 and the heat rejection system 270. The liquid transfer system 250 may include a fluid supply passage 256 to transport cooled dielectric fluid 290 from the heat rejection system 270 to the immersion tank 212. The liquid transfer system 250 may include a fluid return passage 257 to transport warmed dielectric fluid 290 from the immersion tank 212 to the heat rejection system 270. The liquid transfer system 250 may include a dielectric fluid pump 252. The dielectric fluid pump 252 may be located in the fluid supply passage 256 or the fluid return passage 257. The liquid transfer system 250 may include an inlet temperature sensor 253 in the fluid supply passage 256. The liquid transfer system 250 may include an outlet temperature sensor 254 in the fluid return passage 257.

The liquid transfer system may include a reservoir tank 230. The reservoir tank 230 may hold an amount of dielectric fluid 290. The reservoir tank 230 may increase a total dielectric fluid volume of the system 200. The reservoir tank 230 may include a liquid level sensor 231 that is configured to measure a level of the dielectric fluid within the reservoir tank 230.

The heat rejection system 270 may include a fluid loop 276. The fluid loop 276 may include an inlet 271 and an outlet 272. The heat rejection system 270 may include a heat exchanger 274, such as an evaporative cooling tower, dry cooler, or other suitable liquid-to-air heat exchanger. The heat rejection system 270 may include a dielectric fluid pump 273. The dielectric fluid pump 273 may circulate dielectric fluid 290 through the heat exchanger 274. The heat exchanger 274 may reject heat from the dielectric fluid 290 to the environment (e.g., ambient air 850 outside the data center).

The heat rejection system 270 may include a flow meter 275. The heat rejection system 270 may include an inlet temperature sensor 278 located upstream of the heat exchanger 274. The heat rejection system 270 may include an outlet temperature sensor 279 located downstream of the heat exchanger 274. The inlet temperature sensor 278 may determine a temperature of dielectric fluid 290 entering the heat exchanger 274. The outlet temperature sensor 279 may determine a temperature of dielectric fluid 290 exiting the heat exchanger 274.

The single-phase cooling system 200 may be electronically controlled by an electronic control unit 240. The control unit 240 may receive inputs from a plurality of sensors configured to measure flow rates, fluid pressures, fluid temperatures, and fluid levels within the system. Based on the inputs received, the control unit 240 may enable active control of the cooling system 200 by adjusting system settings to match cooling power delivered by the system 200 to cooling demand of the IT equipment 800. The control unit 240 may monitor the sensor inputs in real-time and continuously adjust the system settings to match the cooling power of the system 200 to the cooling demand of the IT equipment 800.

The control unit 240 may be configured to control components of the heat rejection system 270. For example, the control unit 240 may be configured to adjust a rotational speed of one or more heat exchanger fans 280 to increase or decrease air flow through the heat exchanger and thereby adjust a heat rejection rate. The control unit 240 may be configured to adjust a pump speed of the dielectric fluid pump 273 to increase or decrease the dielectric fluid flow rate through the heat exchanger 274.

The control unit 240 may be configured to control components of the liquid transfer system 250. For example, the control unit 240 may be configured to adjust a pump speed of the dielectric fluid pump 252 to increase or decrease a dielectric fluid flow rate between the immersion tank 212 and the heat rejection system 270. The control unit 240 may be configured to adjust the control valve 251 to adjust a pressure differential across the control valve 251.

The control unit 240 may be configured to control components of the power supply system 260. For example, the control unit 240 may be configured to control the power relay 261 and switches 262 of the power supply system 260. The control unit 240 may be configured to throttle power delivery to the IT equipment if the cooling need exceeds the cooling power. The control unit 240 may be configured to halt power delivery to the IT equipment if the cooling power is incapable of meeting the cooling need.

The control unit 240 may be configured to control components of the power supply system 260. For example, the control unit 240 may be configured to control one or more power relays 261 and switches 262 of the power supply system 260. The control unit 240 may be configured to throttle power delivery to the IT equipment if the cooling need exceeds the cooling power. The control unit 240 may be configured to halt power delivery to the IT equipment if the cooling power is incapable of meeting the cooling need.

FIG. 9 shows a heat transfer pathway 900 for the single-phase immersion cooling system 200 of FIG. 8. Waste heat generated by the IT equipment 800 is transferred to the dielectric fluid 290. The warmed dielectric fluid 290 flows through the liquid transfer system 250 to the heat rejection system 270 where it then flows through the liquid-to-air heat exchanger 274. The heat exchanger 274 may include one or more fans 280 that draw air 850 through a radiator of the heat exchanger 274. Heat from the dielectric fluid 290 in the heat exchanger 274 may transfer to air 850 that is drawn through the heat exchanger 274 by the one or more fans 280.

The single-phase immersion cooling system 200 of FIG. 8 may be operated in accordance with the method 1000 of FIG. 1. The method 1000 may serve to assess overall health and performance of the cooling system 200 and its components prior to startup, during operation, and/or after shutdown. The method 1000 may assess system performance in view of a dynamic IT load power and actively adjust the cooling power to match the dynamic IT load power. The method may improve system reliability. The method may improve uptime. The method may improve efficiency.

The step 1005 of providing an immersion cooling system may include providing the actively controlled single-phase immersion cooling system 200. The step 1010 of providing IT equipment 800 may include providing IT equipment and placing the IT equipment into the immersion tank 212 of the single-phase immersion cooling system 100. The IT equipment 800 may be submerged in the dielectric fluid 290. The IT equipment 800 may be positioned below the liquid line 293.

The readiness check 1015 may include testing the readiness of certain components and subsystems of the cooling system 200 before fully powering on the system 200. One purpose of the readiness check 1015 may be to identify any malfunctioning components before the system 200 is powered on. Identifying malfunctioning components prior to powering on the cooling system 200 may allow repairs to be made before startup and thereby minimize unplanned downtime. Performing necessary repairs before startup may reduce the likelihood of powering on the IT equipment 800 and then having to throttle or power off the IT equipment due to a cooling system issue.

The readiness check 1015 may include checking the piping of the heat rejection system 270 for leaks. The readiness check 1015 may include checking the piping of the fluid transfer system 250 for leaks. If a leak is detected, the system 200 may generate a warning notification. If a leak is detected, the system 200 may prevent startup from proceeding until the leak is repaired and no leak is detected.

The readiness check 1015 may include measuring coolant temperature and comparing it to an ambient air 850 temperature.

The readiness check 1015 may include testing a flow rate from the dielectric fluid pump 273. The system readiness check 1015 may include operating the dielectric fluid pump 273 at a minimum speed and then ramping the dielectric fluid pump 273 to a maximum speed. The performance of the dielectric fluid pump 273 may be evaluated by reading an output from the flow meter 275. The performance of the dielectric fluid pump 273 may be evaluated by determining a pressure differential produced by the dielectric fluid pump 273. The pressure differential may be determined by comparing a pressure reading from a first pressure sensor 281 located at the dielectric fluid pump 273 inlet to a pressure reading from a second pressure sensor 282 located at the dielectric fluid pump 273 outlet.

The readiness check 1015 may include detecting a dielectric fluid 290 level in the immersion tank 212. Detecting the dielectric fluid 290 level may include receiving an output from a liquid level sensor 223 mounted in the immersion tank 212. If the fluid level is too low or too high, the system 200 may generate a warning notification. If the fluid level is too low or too high, the system 200 may prevent startup from proceeding until the fluid level is brought within an acceptable range.

The readiness check 1015 may include detecting a dielectric fluid 290 level in the heat exchanger 274. If the dielectric fluid 290 level is too low, the system 200 may generate a warning notification. If the dielectric fluid 290 level is too low, the system 200 may prevent startup from proceeding until a sufficient amount of dielectric fluid 290 is added to the heat exchanger 274.

The readiness check 1015 may include detecting the dielectric fluid 290 level in the reservoir tank 230. If the dielectric fluid 290 level is too low, the system 200 may generate a warning notification. If the dielectric fluid 290 level is too low, the system 200 may prevent startup from proceeding until the issue is resolved.

The readiness check 1015 may include testing the operability of the control valve 251 in the liquid transfer system 250 by opening and closing the control valve 251. The control valve 251 may be deemed functional if it as able to fully open and fully close. If the control valve 251 is unable to fully open or close, the system 200 may generate a warning.

The system readiness check 1015 may include measuring power consumption of a component and determining if the power consumption is within an allowable range. For example, the system readiness check 1015 may include measuring power consumption of the dielectric fluid pump 252 in the heat rejection system 270 and determining if the power consumption is within an allowable range. The system readiness check 1015 may include measuring power consumption of the dielectric fluid pump 252 in the fluid transfer system 250 and determining if the power consumption is within an allowable range. The system readiness check 1015 may include measuring power consumption of the control valve 251 and determining if the power consumption is within an allowable range. The system readiness check 1015 may include measuring power consumption of the heat exchanger fan 280 and determining if the power consumption is within an allowable range. The system readiness check 1015 may include measuring power consumption of one or more of the sensors and determining if their power consumption is within an allowable range. If any component's power consumption is outside a predetermined allowable range, the system 200 may generate a warning notification. If any component's power consumption is outside its allowable range, the system 200 may prevent startup from proceeding until the issue is resolved.

The readiness check 1015 may include checking a status of one or more power relays connected to the IT equipment 800. The system readiness check may include checking status of one or more power relays connected to one or more system components, such as the dielectric fluid pumps (252, 273), control valve 251, or heat exchanger fan 280.

The readiness check 1015 may include measuring fluid pressure in one or more fluid passages of the system 200. The system readiness check 1015 may include determining a pressure drop in the system 200 by comparing pressure measurements at two locations in the system 200. For example, a pressure drop across the heat exchanger 274 may be determined by comparing a pressure measurement at an inlet of the heat exchanger 274 to a pressure measurement at an outlet of the heat exchanger 274. An excessive pressure drop may indicate leakage from the heat exchanger 274.

In one example, the readiness check 1015 may include pumping a predetermined flow of dielectric fluid (e.g., 10 liters per minute) through the fluid loop 276 of the heat rejection system 270. Fluid pressure may be measured at one or more points in the fluid loop 276 to determine if the fluid pressure is within an allowable range (e.g., between 2.5 bar and 3.5 bar). If the fluid pressure is outside of the allowable range, the system 200 may generate a warning notification and prevent startup from proceeding until the issue is resolved. If the pressure is below the allowable range, it may indicate leakage in the plumbing of the fluid loop 276.

In another example, the readiness check 1015 may include operating the heat exchanger 274 at a predetermined duty and providing a predetermined flow of dielectric fluid 290 through the heat exchanger 274. A temperature differential between dielectric fluid 290 entering and exiting the heat exchanger 274 may be determined by measuring and comparing fluid temperatures at the inlet and outlet of the heat exchanger 274. If the temperature differential is lower than an expected theoretical temperature differential, it may indicate that performance of the heat exchanger 274 is impaired, and the heat exchanger 274 may need cleaning or servicing.

The performance check 1020 may include measuring the heat transfer performance of certain subsystems of the system 200 during operation. For example, the performance check 1020 may include measuring the heat transfer performance of the heat rejection system 270 during operation.

The performance check 1020 may include measuring the inlet dielectric fluid 290 temperature of the heat rejection system 270 with the inlet temperature sensor 278. The performance check 1020 may include comparing the inlet dielectric fluid 290 temperature to a range of allowable values and confirming the inlet dielectric fluid 290 temperature is within the range of allowable values. If the inlet dielectric fluid 290 temperature is outside the range of allowable values, the system 200 may generate a warning notification.

The performance check 1020 may include measuring the outlet dielectric fluid 290 temperature of the heat rejection system 270 with the outlet temperature sensor 279. The performance check 1020 may include comparing the outlet dielectric fluid 290 temperature to a range of allowable values and confirming the outlet dielectric fluid 290 temperature is within the range of allowable values. If the outlet dielectric fluid 290 temperature is outside the range of allowable values, the system 200 may generate a warning notification.

The performance check 1020 may include comparing the inlet dielectric fluid 290 temperature to the heat exchanger 274 to the outlet dielectric fluid 290 temperature from the heat exchanger 274 and determining a temperature differential. The performance check 1020 may include comparing the temperature differential to a range of allowable values and confirming the temperature differential is within the range of allowable values. If the temperature differential is outside the range of allowable values, the system 200 may generate a warning notification.

The performance check 1020 may include measuring the dielectric fluid 290 flow rate in the heat rejection system 270 with the flow meter 275. The performance check 1020 may include comparing the dielectric fluid 290 flow rate to a range of allowable values and confirming the dielectric fluid 290 flow rate is within the range of allowable values. If the dielectric fluid 290 flow rate is outside the range of allowable values, the system 200 may generate a warning notification.

The performance check 1020 may include measuring a fan speed of the heat exchanger fan 280 in the heat rejection system 270 with a sensor. The performance check 1020 may include comparing the fan speed to a range of allowable values and confirming the fan speed is within the range of allowable values. If the fan speed is outside the range of allowable values, the system 200 may generate a warning notification.

The performance check 1020 may include measuring the inlet dielectric fluid 290 temperature to the immersion tank 212 with the inlet temperature sensor 253. The performance check 1020 may include comparing the inlet dielectric fluid 290 temperature to a range of allowable values and confirming the inlet dielectric fluid 290 temperature is within the range of allowable values. If the inlet dielectric fluid 290 temperature is outside the range of allowable values, the system 200 may generate a warning notification.

The performance check 1020 may include measuring the outlet dielectric fluid 290 temperature from the immersion tank 212 with the outlet temperature sensor 254. The performance check 1020 may include comparing the outlet dielectric fluid 290 temperature to a range of allowable values and confirming the outlet dielectric fluid 290 temperature is within the range of allowable values. If the outlet dielectric fluid 290 temperature is outside the range of allowable values, the system 200 may generate a warning notification.

The performance check 1020 may include comparing the inlet dielectric fluid 290 temperature to the immersion tank 212 to the outlet dielectric fluid 290 temperature from the immersion tank 212 and determining a temperature differential. The performance check may include comparing the temperature differential to a range of allowable values and confirming the temperature differential is within the range of allowable values. If the temperature differential is outside the range of allowable values, the system 200 may generate a warning notification.

The performance check 1020 may include measuring a dielectric fluid 290 flow rate through the liquid transfer system 250 with the flow meter 255. The performance check 1020 may include comparing the dielectric fluid 290 flow rate to a range of allowable values and confirming the dielectric fluid 290 flow rate is within the range of allowable values. If the dielectric fluid 290 flow rate is outside the range of allowable values, the system 200 may generate a warning notification.

The performance check 1020 may include measuring a temperature in the headspace 214 of the immersion tank 212 with a temperature sensor 221. The performance check 1020 may include comparing the temperature to a range of allowable values and confirming the temperature is within the range of allowable values. If the temperature is outside the range of allowable values, the system 200 may generate a warning notification.

The step 1025 of determining the cooling power of the immersion cooling system 200 may involve determining an actual rate of heat transfer through the system 200. In one example, the cooling power may be substantially equal to a heat rejection rate of the heat exchanger 274. The heat rejection rate of the heat exchanger 274 may be the rate of heat transferred from the dielectric fluid 290 flowing through the heat exchanger 274 to the air 850 outside the data center.

The performance check 1020 may include measuring actual performance of the heat exchanger 274 at rejecting heat to the environment. The performance check 1020 may include determining a heat rejection rate of the heat exchanger 274 based on measured values. In one example, the heat rejection rate may be calculated using the inlet dielectric fluid 290 temperature to the heat exchanger 274, the outlet dielectric fluid 290 temperature from the heat exchanger 274, and the dielectric fluid 290 flow rate through the heat exchanger 274. The inlet dielectric fluid 290 temperature to the heat exchanger 274 may be measured by the inlet temperature sensor 278. The outlet dielectric fluid 290 temperature from the heat exchanger 274 may be measured by the outlet temperature sensor 279. The dielectric fluid 290 flow rate may be measured by the flow meter 275. The heat rejection rate for the heat exchanger 274 may be determined with the following equation:

$$heat rejection {rate}_{heat exchanger} = ( {T}_{inlet} - {T}_{outlet} ) * ( mass flow rate ) * ( heat capacity )$$

where ‘Tᵢₙₗₑₜ’ is a dielectric fluid 290 temperature entering the heat exchanger 274, ‘Tₒᵤₜₗₑₜ’ is the dielectric fluid 290 temperature exiting the heat exchanger 274, ‘mass flow rate’ is a mass flow rate of dielectric fluid 290 through the heat exchanger 274, and ‘heat capacity’ is the heat capacity of the dielectric fluid 290.

The step 1030 of determining the cooling need may include determining the IT load power of the IT equipment 800 within the immersion tank 212. The IT load power may vary with time depending on utilization of the IT equipment. Each piece of IT equipment may fluctuate in power consumption and contribute to IT load power.

The step 1030 of determining the cooling need may include measuring total electric power being consumed by the IT equipment 800. An electric power meter may be used to measure electric power consumption by the IT equipment 800. Since the IT equipment 800 is immersed it the dielectric fluid, it may be assumed that substantially all of the electric power consumed by the IT equipment 800 is converted to heat.

The step 1030 of determining the cooling need may involve the system 200 receiving relevant information from the IT equipment 800 that may be used to calculate the cooling need. For example, the information received from the IT equipment 800 may include CPU utilization rate, CPU temperature, IT equipment temperature, and/or electric power consumption.

The step 1035 of comparing the cooling power to the cooling need may include calculating a power delta between the cooling power and the cooling need.

$$power delta = cooling power - cooling need$$

If the cooling power is equal to the cooling need, no action may be required. If the cooling power is not equal to the cooling need, one or more settings of the immersion cooling system 200 may be adjusted to reduce the power delta. If the cooling power is not equal to the cooling need, one or more settings of the IT equipment 800 may be adjusted to reduce the power delta.

The step 1040 of adjusting a setting of the immersion cooling system 200 may include increasing the dielectric fluid pump 273 speed to increase dielectric fluid 290 flow through the heat exchanger 274 to increase the cooling power. Adjusting a setting of the immersion cooling system 200 may include decreasing the dielectric fluid pump 273 speed to decrease the cooling power.

The step 1040 of adjusting a setting of the immersion cooling system 200 may include increasing the dielectric fluid pump 252 speed to increase the cooling power. Adjusting a setting of the immersion cooling system 200 may include decreasing the dielectric fluid pump 252 speed to decrease the cooling power.

The step 1040 of adjusting a setting of the immersion cooling system 200 may include increasing the heat exchanger fan 280 speed to increase the cooling power. Adjusting a setting of the immersion cooling system 200 may include decreasing the heat exchanger fan 280 speed to decrease the cooling power.

The step 1040 of adjusting a setting of the immersion cooling system 200 may include adjusting an opening angle of the control valve 251.

The step 1040 of adjusting a setting of the IT equipment 800 can include throttling power consumption to reduce the cooling need. Adjusting a setting of the IT equipment 800 can include powering down the IT equipment 800 to reduce the cooling need. Adjusting a setting of the IT equipment 800 can include idling the IT equipment 800 for a period of time.

To avoid weather-induced disruptions, the system 200 may be configured to receive predictive weather information and begin to preemptively adjust system settings to maintain a required cooling power.

System components, such as the control valve 251, dielectric fluid pump 252, dielectric fluid pump 273, and heat exchanger fan 180, may require time to adjust after a setting change has been requested by the control unit 240. For example, the control valve 251 may require several minutes to transition to a target opening angle. The dielectric fluid pumps (252, 273) speed may require several minutes to ramp up or down slowly to a target pump speed. The heat exchanger fan 280 may require several minutes to ramp up or down slowly to a target fan speed setting.

Since the system 200 requires time to respond to changing weather conditions, it may be desirable for the system 200 to predict when the weather will change and begin adjusting system settings in advance. For example, it may be desirable to predict a weather change about 15 minutes in advance to allow the system 200 sufficient time to safely adjust system settings. Due to the high specific heat of the dielectric fluid 290, the system 200 may have considerable thermal mass. Allowing the system 200 sufficient time to adjust settings in preparation for the predicted weather may be desirable to minimize disruption to operation and efficiency.

The system 200 may receive predictive weather information from any suitable source. The system 200 may receive predictive weather information from a weather service. The system 200 may receive predictive weather information from a weather indicator, such as a barometer.

A method 1300 of adjusting system settings of the system 200 based on predicted weather may include a step 1305 of receiving predicted weather information, including a predicted time of a weather change. The method 1300 may include a step 1310 of determining a target immersion cooling system setting based on the predicted weather information. The method 1300 may include a step 1320 of determining a transition time needed to transition from a current immersion cooling system setting to the target immersion cooling system setting. The method may include a step 1325 of ramping the current immersion cooling system setting toward the target immersion cooling system setting prior to the predicted time of the weather change. To allow the system time to fully transition to the target setting before the weather change occurs, the method may include a step 1325 of ramping the current immersion cooling system setting toward the target immersion cooling system setting at least one transition duration prior to the predicted time of the weather change.

An actively controlled single-phase immersion cooling system 300 is shown in FIG. 10. The system 300 may include an immersion tank assembly 310. The system 200 may include a liquid transfer system 350. The system 200 may include a heat exchange system 360. The system 200 may include a heat rejection system 370. The system 300 may include a power supply system 395. The system 300 may include an electronic control unit 340 with programmable logic control.

The immersion tank assembly 310 may include an immersion tank 312. The immersion tank assembly 310 may include an immersion tank 312 partially filled with dielectric fluid 390. IT equipment 800 may be immersed in the dielectric fluid 390. The IT equipment 800 may be connected to electrical power via a power relay. The immersion tank 312 may be enclosed by a lid 218.

The immersion tank 312 may have an upper portion and a lower portion. The upper portion may be located above a liquid line 393. The lower portion may be located below the liquid line 393. The liquid line 393 may be an interface between gases in a headspace 314 of the tank 312 and dielectric liquid in the lower portion of the tank 312. The immersion tank 312 may include a temperature sensor 321 located in the headspace 314 of the tank 312. The immersion tank 312 may include a liquid level sensor 323.

The immersion tank 312 may have an opening in the upper portion. When open, the lid 318 may provide access to an interior volume of the immersion tank 312 to facilitate insertion and removal of IT equipment 800 (e.g., servers, switches, or power electronics). When closed, the lid 318 may enclose the opening and prevent vapor loss. The lid 318 may seal the opening. The lid 318 may hermetically seal the opening.

The liquid transfer system 350 may transfer dielectric fluid 390 between the immersion tank 312 and the heat exchange system 360. The liquid transfer system 350 may include a fluid supply passage 356 to transport cooled dielectric fluid 390 from the heat exchange system 360 to the immersion tank 312. The liquid transfer system 350 may include a fluid return passage 357 to transport warmed dielectric fluid 390 from the immersion tank 312 to the heat exchange system 360. The liquid transfer system 350 may include a dielectric fluid pump 352. The dielectric fluid pump 352 may be located in the fluid supply passage 356 or the fluid return passage 357. The liquid transfer system 350 may include an inlet temperature sensor 353 in the fluid supply passage 356. The liquid transfer system 350 may include an outlet temperature sensor 354 in the fluid return passage 357.

The liquid transfer system 350 may include a reservoir tank 341. The reservoir tank 341 may hold an amount of dielectric fluid 390. The reservoir tank 341 may increase a total dielectric fluid volume of the system 300. The reservoir tank 341 may include a liquid level sensor 342 that is configured to measure a level of the dielectric fluid 390 within the reservoir tank 341.

The heat exchange system 360 may include a heat exchanger 364. The heat exchanger may be a liquid-to-liquid heat exchanger 364. The heat exchanger may be a plate-type heat exchanger 364. The heat exchanger 364 may allow heat to be exchanged between the dielectric fluid 390 and the coolant 377 without mixing the fluids. The heat exchanger 364 may have a first portion having a first inlet and a first outlet. The heat exchanger 364 may have a second portion having and a second inlet and a second outlet. The first inlet and first outlet may be fluidly connected to the liquid transfer system 350 and allow dielectric fluid 390 to flow through the first portion of the heat exchanger 364. The second inlet and outlet may be fluidly connected to the heat rejection system 370 and allow coolant 377 to flow through the second portion of the heat exchanger 364.

The heat exchange system 360 may include a reservoir tank 368. The reservoir tank 368 may hold an amount of coolant 377. The reservoir tank 368 may increase a total coolant volume of the system 300. The reservoir tank 368 may include a liquid level sensor 369 that is configured to measure a level of the coolant 377 within the reservoir tank 368.

The heat exchange system 360 may include a coolant pump 361 to pump coolant 377 through the heat exchanger 364. The heat exchange system 360 may include an inlet temperature sensor 362 to measure a temperature of coolant 377 entering the heat exchanger 364. The heat exchanger 364 may include an outlet temperature sensor 365 to measure a temperature of coolant 377 exiting the heat exchanger 364. The heat exchange system 360 may include an inlet pressure sensor 363 to measure a pressure of coolant 377 entering the heat exchanger 364. The heat exchanger 364 may include an outlet pressure sensor 367 to measure a pressure of coolant 377 exiting the heat exchanger 364.

The heat rejection system 370 may include a fluid loop 376. The fluid loop 376 may include an inlet 371 and an outlet 372. The heat rejection system 370 may include a heat exchanger 374, such as an evaporative cooling tower, dry cooler, or other suitable liquid-to-air heat exchanger. The heat rejection system 370 may include a coolant pump 373. The coolant pump 373 may circulate coolant 377 through the heat exchanger 374. The heat exchanger 374 may reject heat from the coolant 377 to the environment (e.g., air 850 outside the data center).

The heat rejection system 370 may include a flow meter 375. The heat rejection system 370 may include an inlet temperature sensor 378 located upstream of the heat exchanger 374. The heat rejection system 370 may include an outlet temperature sensor 379 located downstream of the heat exchanger 374. The inlet temperature sensor 378 may determine a temperature of coolant 377 entering the heat exchanger 374. The outlet temperature sensor 379 may determine a temperature of coolant 377 the heat exchanger 374.

The single-phase cooling system 300 may be electronically controlled by an electronic control unit 340. The control unit 340 may receive inputs from a plurality of sensors configured to measure flow rates, fluid pressures, fluid temperatures, and fluid levels within the system. Based on the inputs received, the control unit 340 may enable active control of the cooling system 300 by adjusting system settings to match cooling power delivered by the system 300 to cooling demand of the IT equipment 800. The control unit 340 may monitor the sensor inputs in real-time and continuously adjust the system settings to match the cooling power of the system 300 to the cooling demand of the IT equipment 800.

The control unit 340 may be configured to control components of the heat rejection system 370. For example, the control unit 340 may be configured to adjust a rotational speed of one or more heat exchanger fans 380 to increase or decrease air flow through the heat exchanger 374 and thereby adjust the heat rejection rate. The control unit 340 may be configured to adjust a pump speed of the coolant pump 373 to increase or decrease the coolant 377 flow rate through the heat exchanger 374 and thereby adjust the heat rejection rate.

The control unit 340 may be configured to control components of the liquid transfer system 350. For example, the control unit 340 may be configured to adjust a pump speed of the dielectric fluid pump 352 to increase or decrease a dielectric fluid 390 flow rate between the immersion tank 312 and the heat exchange system 360. The control unit 340 may be configured to adjust the control valve 351 to adjust a pressure differential across the control valve 351.

The control unit 340 may be configured to control components of the heat exchange system 360. For example, the control unit 340 may be configured to adjust a pump speed of the coolant pump 361 to increase or decrease the coolant 377 flow rate through the heat exchanger 364.

The control unit 340 may be configured to control components of the power supply system 395. For example, the control unit 340 may be configured to control one or more power relays 396 and switches 397 of the power supply system 395. The control unit 340 may be configured to throttle power delivery to the IT equipment if the cooling need exceeds the cooling power. The control unit 340 may be configured to halt power delivery to the IT equipment if the cooling power is incapable of meeting the cooling need.

FIG. 11 shows a heat transfer pathway 1100 for the single-phase immersion cooling system 300 of FIG. 10. Waste heat generated by the IT equipment 800 is transferred to the dielectric fluid 390. The warmed dielectric fluid 390 flows through the liquid transfer system 350 to the heat exchange system 360 where it then flows through a first portion liquid-to-liquid heat exchanger 364. Within the heat exchanger 364, the heat is transferred to coolant flowing through the second portion of the heat exchanger, thereby warming the coolant 377. The warmed coolant 377 then flows to the heat rejection system 370 where it then flows through the liquid-to-air heat exchanger 374. The heat exchanger 374 may include one or more fans 380 that draw air through a radiator of the heat exchanger 374. Heat from the coolant 377 in the heat exchanger 374 may transfer to air 850 that is drawn through the heat exchanger 374 by the one or more fans 380.

The single-phase immersion cooling system 300 of FIG. 10 may be operated in accordance with the method 1000 of FIG. 1. The method 1000 may serve to assess overall health and performance of the cooling system 300 and its components prior to startup, during operation, and/or after shutdown. The method 1000 may assess system performance in view of a dynamic IT load power and actively adjust the cooling power to match the dynamic IT load power. The method may improve system reliability. The method may improve uptime. The method may improve efficiency.

The step 1005 of providing an immersion cooling system may include providing the actively controlled single-phase immersion cooling system 300. The step 1010 of providing IT equipment 800 may include providing IT equipment 800 and placing the IT equipment 800 into the immersion tank 312 of the single-phase immersion cooling system 300. The IT equipment 800 may be submerged in the dielectric fluid 390. The IT equipment 800 may be positioned below the liquid line 393.

The readiness check 1015 may include testing the readiness of certain components and subsystems of the cooling system 300 before fully powering on the system 300. One purpose of the readiness check 1015 may be to identify any malfunctioning components before the system 300 is powered on. Identifying malfunctioning components prior to powering on the cooling system 300 may allow repairs to be made before startup and thereby minimize unplanned downtime. Performing necessary repairs before startup may reduce the likelihood of powering on the IT equipment 800 and then having to throttle or power off the IT equipment due to a cooling system issue.

The readiness check 1015 may include checking the piping of the fluid transfer system 350 for leaks. The readiness check 1015 may include checking the piping of the heat exchange system 360 for leaks. The readiness check 1015 may include checking the piping of the heat rejection system 370 for leaks. If a leak is detected, the system 300 may generate a warning notification. If a leak is detected, the system 300 may prevent startup from proceeding until the leak is repaired and no leak is detected.

The readiness check 1015 may include measuring the coolant 377 temperature and comparing it to an ambient air 850 temperature. The readiness check 1015 may include testing a coolant 377 flow rate from the coolant pump 373. The system readiness check 1015 may include operating the coolant pump 373 at a minimum speed and then ramping the coolant pump 373 to a maximum speed. The performance of the coolant pump 373 may be evaluated by reading an output from the flow meter 375. The performance of the coolant pump 373 may be evaluated by determining a pressure differential produced by the coolant pump 373. The pressure differential may be determined by comparing a pressure reading from a first pressure sensor 381 located at the coolant pump 373 inlet to a pressure reading from a second pressure sensor 382 located at the coolant pump 373 outlet.

The readiness check 1015 may include detecting a coolant 377 level in the immersion tank 312. Detecting the coolant 377 level may include receiving an output from a liquid level sensor 323 mounted in the immersion tank 312. If the fluid level is too low or too high, the system 300 may generate a warning notification. If the fluid level is too low or too high, the system 300 may prevent startup from proceeding until the fluid level is brought within an acceptable range.

The readiness check 1015 may include detecting a coolant 377 level in the heat exchanger 374. If the coolant 377 level is too low, the system 300 may generate a warning notification. If the coolant 377 level is too low, the system 200 may prevent startup from proceeding until a sufficient amount of coolant 377 is added to the heat exchanger 374.

The readiness check 1015 may include detecting the dielectric fluid 390 level in the reservoir tank 341. If the dielectric fluid 390 level is too low, the system 300 may generate a warning notification. If the dielectric fluid 390 level is too low, the system 300 may prevent startup from proceeding until the issue is resolved.

The readiness check 1015 may include testing the operability of the control valve 351 in the liquid transfer system 350 by opening and closing the control valve 351. The control valve 351 may be deemed functional if it as able to fully open and fully close. If the control valve 351 is unable to fully open or close, the system 300 may generate a warning.

The system readiness check 1015 may include measuring power consumption of a component and determining if the power consumption is within an allowable range. For example, the system readiness check 1015 may include measuring power consumption of the coolant pump 352 in the heat rejection system 370 and determining if the power consumption is within an allowable range. The system readiness check 1015 may include measuring power consumption of the coolant pump 361 in the heat exchange system 360 and determining if the power consumption is within an allowable range. The system readiness check 1015 may include measuring power consumption of the dielectric fluid pump 352 in the fluid transfer system 350 and determining if the power consumption is within an allowable range. The system readiness check 1015 may include measuring power consumption of the control valve 351 and determining if the power consumption is within an allowable range. The system readiness check 1015 may include measuring power consumption of the heat exchanger fan 380 and determining if the power consumption is within an allowable range. The system readiness check 1015 may include measuring power consumption of one or more of the sensors and determining if their power consumption is within an allowable range. If any component's power consumption is outside a predetermined allowable range, the system 300 may generate a warning notification. If any component's power consumption is outside its allowable range, the system 300 may prevent startup from proceeding until the issue is resolved.

The readiness check 1015 may include checking a status of one or more power relays connected to the IT equipment 800. The system readiness check may include checking status of one or more power relays connected to one or more system components, such as the pumps (352, 361, 373), control valve 351, or heat exchanger fan 380.

The readiness check 1015 may include measuring fluid pressure in one or more fluid passages of the system 300. The system readiness check 1015 may include determining a pressure drop in the system 300 by comparing pressure measurements at two locations in the system 300. For example, a pressure drop across the heat exchanger 374 may be determined by comparing a pressure measurement at an inlet of the heat exchanger 374 to a pressure measurement at an outlet of the heat exchanger 374. An excessive pressure drop may indicate coolant leakage from the heat exchanger 374.

In one example, the readiness check 1015 may include pumping a predetermined flow of coolant (e.g., 10 liters per minute) through the fluid loop 376 of the heat rejection system 370. Coolant 377 pressure may be measured at one or more points in the fluid loop 376 to determine if the coolant pressure is within an allowable range (e.g., between 2.5 bar and 3.5 bar). If the coolant pressure is outside of the allowable range, the system 300 may generate a warning notification and prevent startup from proceeding until the issue is resolved. If the coolant pressure is below the allowable range, it may indicate leakage in the plumbing of the fluid loop 376.

In another example, the readiness check 1015 may include operating the heat exchanger 374 at a predetermined duty and providing a predetermined flow of coolant 377 through the heat exchanger 374. A temperature differential between coolant 377 entering and exiting the heat exchanger 374 may be determined by measuring and comparing coolant temperatures at the inlet and outlet of the heat exchanger 374. If the temperature differential is lower than an expected theoretical temperature differential, it may indicate that performance of the heat exchanger 374 is impaired, and the heat exchanger 374 may need cleaning or servicing.

The performance check 1020 may include measuring the heat transfer performance of certain subsystems of the system 300 during operation. For example, the performance check 1020 may include measuring the heat transfer performance of the heat exchange system 360 during operation. The performance check 1020 may include measuring the heat transfer performance of the heat rejection system 270 during operation.

The performance check 1020 may include measuring the inlet coolant 377 temperature of the heat rejection system 370 with the inlet temperature sensor 378. The performance check 1020 may include comparing the inlet coolant 377 temperature to a range of allowable values and confirming the inlet coolant 377 temperature is within the range of allowable values. If the inlet coolant 377 temperature is outside the range of allowable values, the system 300 may generate a warning notification.

The performance check 1020 may include measuring the outlet coolant 377 temperature of the heat rejection system 370 with the outlet temperature sensor 379. The performance check 1020 may include comparing the outlet coolant 377 temperature to a range of allowable values and confirming the outlet coolant 377 temperature is within the range of allowable values. If the outlet coolant 377 temperature is outside the range of allowable values, the system 300 may generate a warning notification.

The performance check 1020 may include comparing the inlet coolant 377 temperature to the heat exchanger 374 to the outlet coolant 377 temperature from the heat exchanger 374 and determining a temperature differential. The performance check 1020 may include comparing the temperature differential to a range of allowable values and confirming the temperature differential is within the range of allowable values. If the temperature differential is outside the range of allowable values, the system 300 may generate a warning notification.

The performance check 1020 may include measuring the coolant 377 flow rate in the heat rejection system 370 with the flow meter 375. The performance check 1020 may include comparing the coolant 377 flow rate to a range of allowable values and confirming the coolant 377 flow rate is within the range of allowable values. If the coolant 377 flow rate is outside the range of allowable values, the system 300 may generate a warning notification.

The performance check 1020 may include measuring a fan speed of the heat exchanger fan 380 in the heat rejection system 370 with a sensor. The performance check 1020 may include comparing the fan speed to a range of allowable values and confirming the fan speed is within the range of allowable values. If the fan speed is outside the range of allowable values, the system 300 may generate a warning notification.

The performance check 1020 may include measuring the inlet dielectric fluid 390 temperature to the immersion tank 312 with the inlet temperature sensor 353. The performance check 1020 may include comparing the inlet dielectric fluid 390 temperature to a range of allowable values and confirming the inlet dielectric fluid 390 temperature is within the range of allowable values. If the inlet dielectric fluid 390 temperature is outside the range of allowable values, the system 300 may generate a warning notification.

The performance check 1020 may include measuring the outlet dielectric fluid 390 temperature from the immersion tank 312 with the outlet temperature sensor 354. The performance check 1020 may include comparing the outlet dielectric fluid 390 temperature to a range of allowable values and confirming the outlet dielectric fluid 390 temperature is within the range of allowable values. If the outlet dielectric fluid 390 temperature is outside the range of allowable values, the system 300 may generate a warning notification.

The performance check 1020 may include comparing the inlet dielectric fluid 390 temperature to the immersion tank 312 to the outlet dielectric fluid 390 temperature from the immersion tank 312 and determining a temperature differential. The performance check may include comparing the temperature differential to a range of allowable values and confirming the temperature differential is within the range of allowable values. If the temperature differential is outside the range of allowable values, the system 300 may generate a warning notification.

The performance check 1020 may include measuring a dielectric fluid 390 flow rate through the liquid transfer system 350 with the flow meter 355. The performance check 1020 may include comparing the dielectric fluid 390 flow rate to a range of allowable values and confirming the dielectric fluid 390 flow rate is within the range of allowable values. If the dielectric fluid 390 flow rate is outside the range of allowable values, the system 300 may generate a warning notification.

The performance check 1020 may include measuring a temperature in the headspace 314 of the immersion tank 312 with a temperature sensor 321. The performance check 1020 may include comparing the temperature to a range of allowable values and confirming the temperature is within the range of allowable values. If the temperature is outside the range of allowable values, the system 300 may generate a warning notification.

The performance check 1020 may include measuring the inlet coolant 377 temperature of the heat exchange system 360 with the inlet temperature sensor 362. The performance check 1020 may include comparing the inlet coolant 377 temperature to a range of allowable values and confirming the inlet coolant 377 temperature is within the range of allowable values. If the inlet coolant 377 temperature is outside the range of allowable values, the system 300 may generate a warning notification.

The performance check 1020 may include measuring the outlet coolant 377 temperature of the heat exchange system 360 with the outlet temperature sensor 365. The performance check 1020 may include comparing the outlet coolant 377 temperature to a range of allowable values and confirming the outlet coolant 377 temperature is within the range of allowable values. If the outlet coolant 377 temperature is outside the range of allowable values, the system 300 may generate a warning notification.

The performance check 1020 may include comparing the inlet coolant 377 temperature to the heat exchanger 364 to the outlet coolant 377 temperature from the heat exchanger 364 and determining a temperature differential. The performance check 1020 may include comparing the temperature differential to a range of allowable values and confirming the temperature differential is within the range of allowable values. If the temperature differential is outside the range of allowable values, the system 300 may generate a warning notification.

The performance check 1020 may include measuring the coolant 377 flow rate in the heat exchange system 360 with the flow meter 366. The performance check 1020 may include comparing the coolant 377 flow rate to a range of allowable values and confirming the coolant 377 flow rate is within the range of allowable values. If the coolant 377 flow rate is outside the range of allowable values, the system 300 may generate a warning notification.

The performance check 1020 may include measuring the inlet coolant 377 pressure of the heat exchange system 360 with the inlet pressure sensor 363. The performance check 1020 may include comparing the inlet coolant 377 pressure to a range of allowable values and confirming the inlet coolant 377 pressure is within the range of allowable values. If the inlet coolant 377 pressure is outside the range of allowable values, the system 300 may generate a warning notification.

The performance check 1020 may include measuring the outlet coolant 377 pressure of the heat exchange system 360 with the outlet pressure sensor 367. The performance check 1020 may include comparing the outlet coolant 377 pressure to a range of allowable values and confirming the outlet coolant 377 pressure is within the range of allowable values. If the outlet coolant 377 pressure is outside the range of allowable values, the system 300 may generate a warning notification.

The performance check 1020 may include comparing the inlet coolant 377 pressure to the heat exchanger 364 to the outlet coolant 377 pressure from the heat exchanger 364 and determining a pressure differential. The performance check 1020 may include comparing the pressure differential to a range of allowable values and confirming the pressure differential is within the range of allowable values. If the pressure differential is outside the range of allowable values, the system 300 may generate a warning notification.

The step of determining the cooling power 1025 of the immersion cooling system 300 may involve determining an actual rate of heat transfer through the system 300. In one example, the cooling power may be substantially equal to a heat transfer rate of the heat exchanger 364 in the heat exchange system 360. The heat removal rate of the heat exchanger 364 may be the rate of heat transferred from the dielectric fluid 390 to the coolant 377 within the heat exchanger 364. In another example, the cooling power may be substantially equal to a heat rejection rate of the heat exchanger 374. The heat rejection rate of the heat exchanger 374 may be the rate of heat transferred from the coolant 377 flowing through the heat exchanger 374 to the air 850 outside the data center.

The heat transfer rate of the heat exchanger 364 may be determined from measured values while the system 300 is operating. In one example, the heat transfer rate through the heat exchanger 364 may be calculated from measured values, including an inlet coolant temperature to the heat exchanger 364, an outlet coolant temperature from the heat exchanger 364, and a coolant flow rate through the heat exchanger 364. The inlet coolant temperature may be measured by the inlet temperature sensor 353. The outlet coolant temperature may be measured by the outlet temperature sensor 354. The coolant flow rate may be measured by the flow meter 355. The heat transfer rate through the heat exchanger 364 may be determined by the following equation:

heat removal rate_{condenser}=(Tₒᵤₜₗₑₜ−Tᵢₙₗₑₜ)*(mass flow rate)*(heat capacity)

where ‘Tᵢₙₗₑₜ’ is the coolant 377 temperature entering the heat exchanger 364, ‘Tₒᵤₜₗₑₜ’ is the coolant 377 temperature exiting the heat exchanger 364, ‘mass flow rate’ is a mass flow rate of coolant 377 through the heat exchanger 364, and ‘heat capacity’ is the heat capacity of the coolant 377.

The performance check 1020 may include measuring actual performance of the heat exchanger 374 at rejecting heat to the environment. The performance check 1020 may include determining a heat rejection rate of the heat exchanger 374 based on measured values. In one example, the heat rejection rate may be calculated using the inlet coolant 377 temperature to the heat exchanger 374, the outlet coolant 377 temperature from the heat exchanger 374, and the coolant 377 flow rate through the heat exchanger 374. The inlet coolant 377 temperature to the heat exchanger 374 may be measured by the inlet temperature sensor 378. The outlet coolant 377 temperature from the heat exchanger 374 may be measured by the outlet temperature sensor 379. The coolant 377 flow rate may be measured by the flow meter 375. The heat rejection rate for the heat exchanger 374 may be determined with the following equation:

$$heat rejection {rate}_{hx} = ( {T}_{inlet} - {T}_{outlet} ) * ( mass flow rate ) * ( heat capacity )$$

where ‘Tᵢₙₗₑₜ’ is the coolant 377 temperature entering the heat exchanger 374, ‘Tₒᵤₜₗₑₜ’ is the coolant 377 temperature exiting the heat exchanger 374, ‘mass flow rate’ is a mass flow rate of coolant 377 through the heat exchanger 374, and ‘heat capacity’ is the heat capacity of the coolant 377.

The step of determining the cooling need may include determining the IT load power of the IT equipment 800 within the immersion tank 312. The IT load power may vary with time depending on utilization of the IT equipment 800. Each piece of IT equipment 800 may fluctuate in power consumption and contribute to IT load power.

The step of determining the cooling need may include measuring total electric power being consumed by the IT equipment 800. An electric power meter may be used to measure electric power consumption by the IT equipment 800. Since the IT equipment 800 is immersed it the dielectric fluid, it may be assumed that substantially all of the electric power consumed by the IT equipment 800 is converted to heat.

The step of determining the cooling need may involve the system 300 receiving relevant information from the IT equipment 800 that may be used to calculate the cooling need. For example, the information received from the IT equipment 800 may include CPU utilization rate, CPU temperature, IT equipment temperature, and/or electric power consumption.

The step 1035 of comparing the cooling power to the cooling need may include calculating a power delta between the cooling power and the cooling need.

$$power delta = cooling power - cooling need$$

If the cooling power is equal to the cooling need, no action may be required. If the cooling power is not equal to the cooling need, one or more settings of the immersion cooling system 300 may be adjusted to reduce the power delta. If the cooling power is not equal to the cooling need, one or more settings of the IT equipment 800 may be adjusted to reduce the power delta.

The step 1040 of adjusting a setting of the immersion cooling system 300 may include increasing the coolant pump 373 speed to increase coolant 377 flow through the heat exchanger 374 to increase the cooling power. Adjusting a setting of the immersion cooling system 300 may include decreasing the coolant pump 373 speed to decrease the cooling power.

The step 1040 of adjusting a setting of the immersion cooling system 300 may include increasing the coolant pump 361 speed to increase coolant 377 flow through the heat exchanger 364 to increase the cooling power. Adjusting a setting of the immersion cooling system 300 may include decreasing the coolant pump 361 speed to decrease the cooling power.

The step 1040 of adjusting a setting of the immersion cooling system 300 may include increasing the dielectric fluid pump 352 speed to increase the cooling power. Adjusting a setting of the immersion cooling system 300 may include decreasing the dielectric fluid pump 352 speed to decrease the cooling power.

The step 1040 of adjusting a setting of the immersion cooling system 300 may include increasing the heat exchanger fan 380 speed to increase the cooling power. Adjusting a setting of the immersion cooling system 300 may include decreasing the heat exchanger fan 380 speed to decrease the cooling power.

The step 1040 of adjusting a setting of the immersion cooling system 300 may include adjusting an opening angle of the control valve 351.

The step 1040 of adjusting a setting of the IT equipment 800 can include throttling power consumption to reduce the cooling need. Adjusting a setting of the IT equipment 800 can include powering down the IT equipment 800 to reduce the cooling need. Adjusting a setting of the IT equipment 800 can include idling the IT equipment 800 for a period of time.

To avoid weather-induced disruptions, the system 200 may be configured to receive predictive weather information and begin to preemptively adjust system settings to maintain a required cooling power.

System components, such as the control valve 251, dielectric fluid pump 252, dielectric fluid pump 273, and heat exchanger fan 180, may require time to adjust after a setting change has been requested by the control unit 240. For example, the control valve 251 may require several minutes to transition to a target opening angle. The dielectric fluid pumps (252, 273) speed may require several minutes to ramp up or down slowly to a target pump speed. The heat exchanger fan 280 may require several minutes to ramp up or down slowly to a target fan speed setting.

Since the system 200 requires time to respond to changing weather conditions, it may be desirable for the system 200 to predict when the weather will change and begin adjusting system settings in advance. For example, it may be desirable to predict a weather change about 15 minutes in advance to allow the system 200 sufficient time to safely adjust system settings. Due to the high specific heat of the dielectric fluid 290, the system 200 may have considerable thermal mass. Allowing the system 200 sufficient time to adjust settings in preparation for the predicted weather may be desirable to minimize disruption to operation and efficiency.

The system 200 may receive predictive weather information from any suitable source. The system 200 may receive predictive weather information from a weather service. The system 200 may receive predictive weather information from a weather indicator, such as a barometer.

A method 1300 of adjusting system settings of the system 200 based on predicted weather may include a step 1305 of receiving predicted weather information, including a predicted time of a weather change. The method 1300 may include a step 1310 of determining a target immersion cooling system setting based on the predicted weather information. The method 1300 may include a step 1320 of determining a transition time needed to transition from a current immersion cooling system setting to the target immersion cooling system setting. The method may include a step 1325 of ramping the current immersion cooling system setting toward the target immersion cooling system setting prior to the predicted time of the weather change. To allow the system time to fully transition to the target setting before the weather change occurs, the method may include a step 1325 of ramping the current immersion cooling system setting toward the target immersion cooling system setting at least one transition duration prior to the predicted time of the weather change.

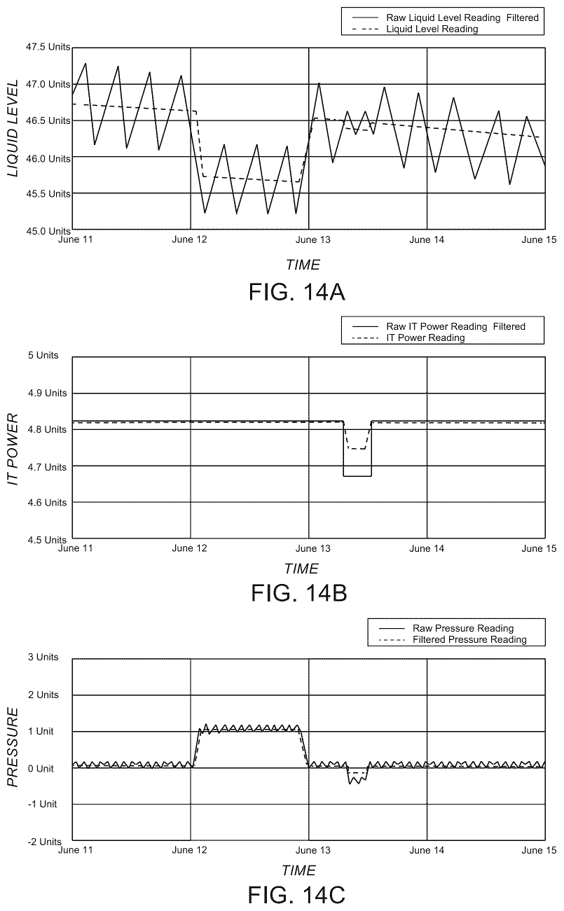

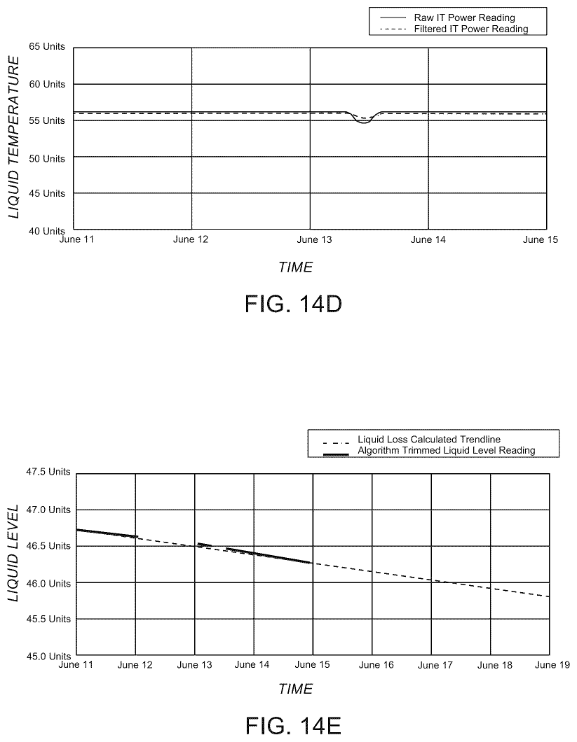

FIG. 14A shows a plot of liquid level (193) as measured by the liquid level sensor (123, 322) over a period of time. The signal from the liquid level sensor may be filtered by a computer-controlled subsystem (140, 340). The system may determine if, and by how much, the liquid level (193) has decreased during operation. Detecting and quantifying the magnitude of changes in liquid level may allow the system 100 to determine when to increase cooling power, for example, by increasing the rate of heat rejection from the heat rejection system 370. By increasing cooling power in response to determining that the liquid level is low, the system 100 may prevent the IT equipment 800 from throttling down performance or shutting down.

FIG. 14B shows IT power consumption over the period of time. IT power may be measured by the control unit (140, 340). A decrease in IT power consumption may result in an increase in the dielectric liquid level (193) as vapor returns to liquid and returns to the fluid bath. In another example, a decrease in IT power consumption may indicate dielectric fluid loss. Referring to FIGS. 14A and 14B, the time period of decreased power consumption may coincide with an increase in liquid level, as shown for the period between June 13 and June 14.

FIG. 14C shows immersion tank pressure (133) over the period of time. Referring to FIGS. 14A and 14C, the increase in immersion tank pressure in FIG. 14A between June 12 and June 13 corresponds to a decrease in liquid level in FIG. 14A, which may be due to several factors including increased vaporization of dielectric fluid as IT power consumption increases, reduced performance of the heat rejection system 370, or elastic deformation of the immersion tank due to changes in tank pressure.

FIG. 14D shows a plot of measured dielectric fluid temperature over the period of time. The decrease in temperature shown in FIG. 14D corresponds with the decrease in pressure shown in FIG. 14C.

FIG. 14E shows a plot of fluid loss from within the immersion tank system (100, 300) over the period of time. The density of dielectric liquid varies with temperature, so the fluid volume and the resultant liquid level changes with fluid temperature. As fluid temperature increases, the vapor pressure within the headspace increases and serves to expand the internal tank volume (like a balloon, but to a much lesser extent). In the same sense, negative pressure serves to collapse the tank and reduce its internal volume. An increase in IT power consumption may increase the quantity of vapor bubbles produced inside the liquid, thereby causing displacing volume.

The elements and method steps described herein can be used in any combination whether explicitly described or not. All combinations of method steps as described herein can be performed in any order, unless otherwise specified or clearly implied to the contrary by the context in which the referenced combination is made.

As used herein, the singular forms “a,” “an,” and “the” include plural referents unless the content clearly dictates otherwise.

As used herein, the unit “psig” represents gauge pressure in pounds per square inch. A positive value indicates a pressure above atmospheric pressure. A negative value indicates a pressure below atmospheric pressure.

As used herein, the term “fluidly connected” can describe a first component directly connected to a second component or a first component indirectly connected to a second component by way of one or more intervening components, where fluid, in gas form, liquid form, or a two-phase mixture, may pass from the first component to the second component without escaping to the atmosphere.

Numerical ranges as used herein are intended to include every number and subset of numbers contained within that range, whether specifically disclosed or not. Further, these numerical ranges should be construed as providing support for a claim directed to any number or subset of numbers in that range. For example, a disclosure of 1-10 should be construed as supporting a range of from 2 to 8, from 3 to 7, from 5 to 6, from 1 to 9, from 3.6 to 4.6, from 3.5 to 9.9, and so forth.

The methods and compositions of the present invention can comprise, consist of, or consist essentially of the essential elements and limitations described herein, as well as any additional or optional steps, components, or limitations described herein or otherwise useful in the art.

It is understood that the invention is not confined to the particular construction and arrangement of parts herein illustrated and described, but embraces such modified forms thereof as come within the scope of the claims.

The foregoing description has been presented for purposes of illustration and description. It is not intended to be exhaustive or to limit the claims to the embodiments disclosed. Other modifications and variations may be possible in view of the above teachings. The embodiments were chosen and described to explain the principles of the invention and its practical application to enable others skilled in the art to best utilize the invention in various embodiments and various modifications as are suited to the particular use contemplated. It is intended that the claims be construed to include other alternative embodiments of the invention except insofar as limited by the prior art.

What is claimed is:

1. A method of operating an immersion cooling system, the method comprising:
providing an immersion cooling system;
providing IT equipment to be cooled by the immersion cooling system;
performing a readiness check of the immersion cooling system;
performing a performance check of the immersion cooling system;
determining a cooling power of the immersion cooling system;
determining a cooling need of the IT equipment;
determining a power delta, wherein the power delta is a difference between the cooling power and the cooling need; and
adjusting a setting of the immersion cooling system or a setting of the IT equipment to reduce the power delta if the power delta is nonzero.

2. The method of claim 1, wherein performing the readiness check comprises:
testing a system component prior to starting the immersion cooling system;
determining if a measured value of the system component is within a range of allowable values;
issuing a warning notification if the measured value is outside the range of allowable values; and
preventing the immersion cooling system from starting until the measured value is within the range of allowable values.

3. The method of claim 1, wherein performing the performance check comprises:
determing a performance value of a subsystem of the immersion cooling system based on measured values during operation of the immersion cooling system;
determining if the performance value is within a range of allowable values; and
issuing a warning notification if the performance value is outside the range of allowable values.

4. The method of claim 1, wherein determining the cooling power of the immersion cooling system comprises:
measuring a heat removal rate of a condenser within an immersion tank of the immersion cooling system,
wherein the condenser is configured to transfer heat from a dielectric vapor in the immersion tank to coolant flowing through the condenser.

5. The method of claim 1, wherein determining the cooling power of the immersion cooling system comprises:
measuring a heat rejection rate of a heat exchanger of the immersion cooling system,
wherein the heat exchanger is configured to transfer heat from a coolant to ambient air.

6. The method of claim 1, wherein determining the cooling need of the IT equipment comprises measuring real-time electric power consumption by the IT equipment.

7. The method of claim 1, wherein determining the cooling need of the IT equipment comprises measuring a dielectric vapor temperature in a headspace of an immersion tank of the immersion cooling system.

8. The method of claim 1, wherein adjusting a setting of the immersion cooling system to reduce the power delta comprises adjusting at least one of a coolant pump speed setting, a heat exchanger fan speed setting, or a control valve setting with a PID controller.

9. The method of claim 1, wherein adjusting a setting of the IT equipment to reduce the power delta comprises throttling electric power supplied to the IT equipment, idling the IT equipment, or powering down the IT equipment.

10. An actively controlled immersion cooling system comprising:
an electronic control unit configured to:
perform a readiness check of an immersion cooling system;
perform a performance check of the immersion cooling system;
determine a cooling power of the immersion cooling system;
determine a cooling need of IT equipment to be cooled;
determine a power delta, wherein the power delta is a difference between the cooling power and the cooling need; and
adjust a setting of the immersion cooling system or a setting of the IT equipment to reduce the power delta if the power delta is nonzero.

11. The actively controlled immersion cooling system of claim 10, further comprising:
an immersion tank having an upper portion and a lower portion; and
an array of temperature sensors comprising a plurality of temperature sensors arranged vertically in the upper portion of the immersion tank,
the electronic control unit further configured to:
determine a height of concentrated vapor zone using one of more temperature sensors; and
adjust a setting of the immersion cooling system or a setting of the IT equipment to until the height of concentrated vapor zone is within a range of pre-determined values.

12. The actively controlled immersion cooling system of claim 10, wherein determining a cooling power of the immersion cooling system comprises determining a heat rejection rate of a liquid-to-air heat exchanger.

13. A method of adjusting system settings of an immersion cooling system based on predicted weather information, the method comprising:
receiving a predicted weather information, including a predicted time of a weather change;
determining a target immersion cooling system setting based on the predicted weather information;
determining a transition time needed to transition from a current immersion cooling system setting to the target immersion cooling system setting; and
ramping the current immersion cooling system setting toward the target immersion cooling system setting prior to the predicted time of the weather change.

14. The method of claim 13, wherein the predicted weather information comprises a predicted air temperature, a predicted humidity, and a predicted wind speed.

15. The method of claim 13, wherein the target immersion cooling system setting is a target pump speed, a target heat exchanger fan speed, or a target control valve setting.

16. The method of claim 13, wherein ramping the current immersion cooling system setting toward the target immersion cooling system setting prior to the predicted time of the weather change comprises ramping the current immersion cooling system setting toward the target immersion cooling system setting at least one transition duration prior to the predicted time of the weather change.

17. The method of claim 13, further comprising issuing a warning notification if the current immersion cooling system setting cannot be ramped to the target immersion cooling system setting prior to the predicted time of the weather change.

18. An actively controlled immersion cooling system configured to adjust system settings based on predicted weather information, the system comprising:
an electronic control unit configured to:
receive predicted weather information, including a predicted time of a weather change;
determine a target immersion cooling system setting based on the predicted weather information;
determine a transition time needed to transition from a current immersion cooling system setting to the target immersion cooling system setting; and
ramp the current immersion cooling system setting toward the target immersion cooling system setting prior to the predicted time of the weather change.

19. The actively controlled immersion cooling system of claim 18, wherein the predicted weather comprises a predicted air temperature, a predicted humidity, or a predicted wind speed.

20. The actively controlled immersion cooling system of claim 18, wherein the target immersion cooling system setting is a target pump speed, a target heat exchanger fan speed, or a target control valve setting.
